(19) United States
(12) Patent Application Publication
(10) Pub. No.: US 2024/0395551 A1
(43) Pub. Date: Nov. 28, 2024

(54) PHOTOSENSITIVE COMPOSITION, TRANSFER FILM, CURED FILM, SEMICONDUCTOR PACKAGE, PATTERN FORMING METHOD, AND MANUFACTURING METHOD OF SEMICONDUCTOR PACKAGE

(71) Applicant: FUJIFILM Corporation, Tokyo (JP)

(72) Inventors: Keigo YAMAGUCHI, Kanagawa (JP); Kunihiko KODAMA, Kanagawa (JP)

(73) Assignee: FUJIFILM Corporation, Tokyo (JP)

(21) Appl. No.: 18/789,267

(22) Filed: Jul. 30, 2024

Related U.S. Application Data
(63) Continuation of application No. PCT/JP2023/001940, filed on Jan. 23, 2023.

(30) Foreign Application Priority Data
Jan. 31, 2022 (JP) 2022-013385

(51) Int. Cl. H01L 21/027; G03F 7/004; G03F 7/038; G03F 7/32; H01L 21/02; H01L 21/683

(52) U.S. Cl. CPC H01L 21/0275; G03F 7/0045; G03F 7/038; G03F 7/322; H01L 21/02697; H01L 21/6836; H01L 2221/68359

(57) ABSTRACT

An object of the present invention is to provide a photosensitive composition capable of forming a pattern having a low coefficient of thermal expansion and a high glass transition temperature; a transfer film; a cured film; a semiconductor package; a pattern forming method; and a manufacturing method of a semiconductor package. The photosensitive composition of the present invention contains a compound A having a carboxy group, a compound β having a structure in which an amount of the carboxy group included in the compound A is decreased by exposure, and a filler.

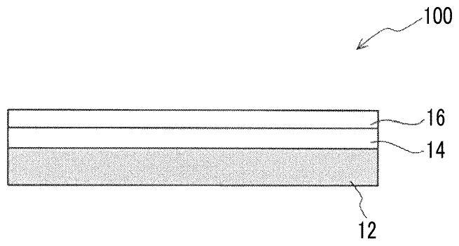

### CROSS-REFERENCE TO RELATED APPLICATIONS

This application is a Continuation of PCT International Application No. PCT/JP2023/001940 filed on Jan. 23, 2023, which claims priority under 35 U.S.C. § 119(a) to Japanese Patent Application No. 2022-013385 filed on Jan. 31, 2022. The above applications are hereby expressly incorporated by reference, in their entirety, into the present application.

### BACKGROUND OF THE INVENTION

### 1. Field of the Invention

The present invention relates to a photosensitive composition, a transfer film, a cured film, a semiconductor package, a pattern forming method, and a manufacturing method of a semiconductor package.

In a display device provided with a touch panel such as a capacitive input device (specifically, a display device such as an organic electroluminescence (EL) display device and a liquid crystal display device), a conductive pattern such as an electrode pattern corresponding to a sensor in a visual recognition portion and a wiring line for a peripheral wiring portion and a lead-out wiring portion is provided inside the touch panel.

In general, a photosensitive composition is used for forming a patterned layer (hereinafter, also simply referred to as “pattern”).

For example, JP1989-032255A (JP-H01-032255A) discloses a photosensitive resin composition (photosensitive composition) having a predetermined configuration.

### SUMMARY OF THE INVENTION

As a result of studying formation of a pattern using the photosensitive composition having the configuration as described in JP1989-032255A (JP-H01-032255A), the present inventors have found that the formed pattern exhibits at least one characteristic of a high coefficient of thermal expansion (CTE) or a low glass transition temperature (Tg).

An object of the present invention is to provide a photosensitive composition capable of forming a pattern having a low CTE and a high Tg. Another object of the present invention is to provide a transfer film, a cured film, a semiconductor package, a pattern forming method, and a manufacturing method of a semiconductor package, which are related to the photosensitive composition.

As a result of intensive studies to achieve the above-described objects, the present inventors have found that the above-described objects can be achieved by the following configurations, and have completed the present invention.

[1]

A photosensitive composition comprising:
a compound A having a carboxy group;
a compound β having a structure in which an amount of the carboxy group included in the compound A is decreased by exposure; and
a filler.
   [2]

The photosensitive composition according to [1],
in which the compound β is a compound B having a structure capable of accepting an electron from the carboxy group included in the compound A in a photoexcited state.
   [3]

The photosensitive composition according to [2],
in which a total number of structures capable of accepting the electron, included in the compound B, is 3 mol % or more with respect to a total number of carboxy groups included in the compound A.
   [4]

The photosensitive composition according to any one of [1] to [3],
in which the compound A includes at least one selected from the group consisting of an acrylic resin having a carboxy group, a carboxylic acid-modified epoxy (meth)acrylate resin, a modified phenol resin having a carboxy group, and a compound having a carboxy group and a bisphenol structure.
   [5]

The photosensitive composition according to any one of [1] to [4],
in which an acid value of the compound A is 30 to 500 mgKOH/g.
   [6]

The photosensitive composition according to any one of [1] to [5],
in which the compound β includes at least one selected from the group consisting of acridine, 9-methylacridine, and 9-phenylacridine.
   [7]
The photosensitive composition according to any one of [1] to [6], in which a molar absorption coefficient of the compound β at a wavelength of 365 nm is more than 1,000 L/(mol cm).
   [8]

The photosensitive composition according to any one of [1] to [7],
in which the filler includes at least one selected from the group consisting of silicon dioxide, boron nitride, barium sulfate, and silicate.
   [9]

The photosensitive composition according to any one of [1] to [8],
in which a content of the filler is 10% to 80% by mass with respect to a total solid content of the photosensitive composition.
   [10]

The photosensitive composition according to any one of [1] to [9],
in which an average primary particle diameter of the filler is 5 to 1,000 nm.
   [11]

The photosensitive composition according to any one of [1] to [10],
in which an average primary particle diameter of the filler is 10 to 300 nm.
   [12]

The photosensitive composition according to any one of [1] to [11],
in which a refractive index of the filler is 1.2 to 1.8.
   [13]

The photosensitive composition according to any one of [1] to [12],
in which the filler is subjected to a surface treatment.
   [14]

The photosensitive composition according to any one of [1] to [13], further comprising: an epoxy compound.

[15]

The photosensitive composition according to [14],
in which the epoxy compound includes at least one selected from the group consisting of a bisphenol A-type epoxy resin, a bisphenol F-type epoxy resin, a biphenyl-type epoxy resin, a phenol novolac-type epoxy resin, a cresol novolac-type epoxy resin, and a urethane epoxy-type epoxy resin.
   [16]

The photosensitive composition according to [14] or [15],
in which the epoxy compound has two or more epoxy groups in one molecule.
   [17]

The photosensitive composition according to any one of [14] to [16],
in which an epoxy value of the epoxy compound is 90 to 290 g/eq.
   [18]

The photosensitive composition according to any one of [1] to [17],
in which the photosensitive composition contains no polymerizable compound having a molecular weight of 2,000 or less, having an ethylenically unsaturated group, and not having a carboxy group, or
in a case of containing the polymerizable compound, a content of the polymerizable compound is 5% by mass or less with respect to a total solid content of the photosensitive composition.
   [19]

The photosensitive composition according to any one of [1] to [18],
in which the photosensitive composition is capable of forming a photosensitive layer which can be patterned by exposure and development with an aqueous solution of 1% by mass sodium carbonate at a liquid temperature of 25° C.
   [20]

The photosensitive composition according to any one of [1] to [19],
in which a content of the compound A is 15% by mass or more with respect to a total solid content of the photosensitive composition,
a content of the compound β is 1% by mass or more with respect to the total solid content of the photosensitive composition,
a content of the filler is 10% to 80% by mass with respect to the total solid content of the photosensitive composition,
a mass ratio of the content of the filler to the content of the compound A is 0.5 or more,
a mass ratio of the content of the compound β with respect to the content of the compound A is 0.7 or less, and
a mass ratio of the content of the compound β to the content of the filler is 0.5 or less.
   [21]

A transfer film comprising:
a temporary support; and
a photosensitive layer formed of the photosensitive composition according to any one of [1] to [20].
   [22]

A cured film obtained by curing the photosensitive composition according to any one of [1] to [20].

[23]

A semiconductor package comprising:
the cured film according to [22].
   [24]

A pattern forming method comprising, in the following order:
a step of forming a photosensitive layer on a base material using the photosensitive composition according to any one of [1] to [20] or the transfer film according to [21];
a step of exposing the photosensitive layer in a patterned manner; and
a step of developing the exposed photosensitive layer with an alkali developer to form a pattern.
   [25]

A manufacturing method of a semiconductor package comprising, in the following order:
a step of forming a photosensitive layer on a base material having a conductive layer, using the photosensitive composition according to any one of [1] to [20] or the transfer film according to [21];
a step of exposing the photosensitive layer in a patterned manner;
a step of developing the exposed photosensitive layer with an alkali developer to form a pattern having a via; and
a step of forming a circuit pattern on the pattern.

According to the present invention, it is possible to provide a photosensitive composition capable of forming a pattern having a low CTE and a high Tg. In addition, it is possible to provide a transfer film, a cured film, a semiconductor package, a pattern forming method, and a manufacturing method of a semiconductor package, which are related to the photosensitive composition.

### BRIEF DESCRIPTION OF THE DRAWINGS

The FIGURE is a schematic view showing an example of a layer configuration of a transfer film.

### DESCRIPTION OF THE PREFERRED EMBODIMENTS

Hereinafter, the present invention will be described in detail.

In the present specification, a numerical range expressed using “to” means a range that includes the proceeding and succeeding numerical values of “to” as a lower limit value and an upper limit value, respectively.

In addition, regarding numerical ranges that are described stepwise in the present specification, an upper limit value or a lower limit value described in a numerical range may be replaced with an upper limit value or a lower limit value of another stepwise numerical range. In addition, regarding the numerical range described in the present specification, an upper limit value or a lower limit value described in a numerical value may be replaced with a value described in Examples.

In addition, a term “step” in the present specification includes not only an independent step but also a step that cannot be clearly distinguished from other steps, as long as the intended purpose of the step is achieved.

In the present specification, a temperature condition may be set to 25° C. unless otherwise specified. For example, unless otherwise specified, a temperature at which each of the above-described steps is performed may be 25° C.

In the present specification, “transparent” means that an average transmittance of visible light having a wavelength of 400 nm to 700 nm is 80% or more, preferably 90% or more.

In addition, the average transmittance of visible light is a value measured by using a spectrophotometer, and for example, can be measured by using a spectrophotometer U-3310 manufactured by Hitachi, Ltd.

In the present specification, “actinic ray” or “radiation” means, for example, a bright line spectrum of a mercury lamp such as g-rays, h-rays and i-rays, or far ultraviolet rays typified by an excimer laser, extreme ultraviolet rays (EUV light), X-rays, electron beams (EB). In addition, in the present specification, light means the actinic ray or the radiation.

Unless otherwise specified, “exposure” in the present specification encompasses not only exposure by a mercury lamp, far ultraviolet rays typified by an excimer laser, extreme ultraviolet rays, X-rays, EUV light, or the like, but also exposure of drawing by corpuscular beams such as electron beams and ion beams.

In the present specification, unless otherwise specified, a content ratio of each repeating unit of a polymer is a molar ratio.

In addition, in the present specification, a refractive index is a value measured with an ellipsometer at a wavelength of 550 nm unless otherwise specified.

In the present specification, unless otherwise specified, a molecular weight in a case of a molecular weight distribution is a weight-average molecular weight. In the present specification, a weight-average molecular weight is a value obtained by performing polystyrene conversion of a value measured by gel permeation chromatography (GPC).

In the present specification, “(meth)acrylic acid” is a concept including both acrylic acid and a methacrylic acid, “(meth)acryloyl group” is a concept including both acryloyl group and methacryloyl group, and “(meth)acrylate” has a concept including both acrylate and methacrylate.

In the present specification, “water-soluble” means that the solubility in 100 g of water with a pH of 7.0 at a liquid temperature of 22° C. is 0.1 g or more.

“Solid content” of a composition means a component forming a composition layer (for example, a photosensitive layer or the like) formed of the composition (for example, a photosensitive composition or the like), and in a case where the composition contains a solvent (for example, organic solvent, water, and the like), the solid content means all components excluding the solvent. In addition, in a case where the components are components which form a composition layer, the components are considered to be solid contents even in a case where the components are liquid components.

In the present specification, unless otherwise specified, a thickness of a layer (film thickness) is an average thickness measured using a scanning electron microscope (SEM) for a thickness of 0.5 μm or more, and is an average thickness measured using a transmission electron microscope (TEM) for a thickness of less than 0.5 μm. The above-described average thickness is an average thickness obtained by producing a section to be measured using an ultramicrotome, measuring thicknesses of any five points, and arithmetically averaging the values.

### [Photosensitive Composition]

The photosensitive composition according to the embodiment of the present invention contains a compound A having a carboxy group, a compound β having a structure in which an amount of the carboxy group included in the compound A is decreased by exposure, and a filler.

Although the detailed action mechanism of the photosensitive composition according to the embodiment of the present invention is not clear, the present inventors have presumed as follows. It is presumed that a pattern (cured film) obtained by exposing and developing a photosensitive layer formed of the photosensitive composition according to the embodiment of the present invention has a low CTE and a high Tg, because a content of the carboxy group included in the compound A is reduced by the compound β, and the filler is contained.

Hereinafter, the fact that at least one of the effect of further reducing the CTE of the pattern to be formed or the effect of further increasing the Tg of the pattern to be formed is obtained is also referred to as “effect of the present invention is more excellent”.

Hereinafter, an example of an embodiment of the photosensitive composition will be described.

### Embodiment X-1-a1

A photosensitive composition containing: a compound A; a compound β; and a filler, in which the photosensitive composition does not substantially contain a polymerizable compound and a photopolymerization initiator.

### Embodiment X-1-a2

A photosensitive composition containing: a compound A; a compound β; and a filler, in which the photosensitive composition does not substantially contain a photopolymerization initiator.

### Embodiment X-1-a3

A photosensitive composition containing: a compound A; a compound β; and a filler, in which the photosensitive composition contains a polymerizable compound and a photopolymerization initiator.

In the embodiment X-1-a1, the “does not substantially contain a polymerizable compound” means that a content of the polymerizable compound may be 5% by mass or less, preferably less than 3% by mass, more preferably 1% by mass or less, and still more preferably 0.1% by mass or less with respect to the total solid content of the photosensitive composition.

In the embodiment X-1-a1 and the embodiment X-1-a2, the “does not substantially contain a photopolymerization initiator” means that a content of the photopolymerization initiator may be less than 0.1% by mass, preferably 0% to 0.05% by mass and more preferably 0% to 0.01% by mass with respect to the total solid content of the photosensitive composition.

In the embodiments X-1-a1 to X-1-a3, the “polymerizable compound” is a polymerizable compound having no carboxy group and having an ethylenically unsaturated group, which will be described later.

The embodiment X-1-a1 or the embodiment X-1-a2 is preferable, and the embodiment X-1-a1 is more preferable.

In addition, as a suitable range of each component in the photosensitive composition, it is also preferable that a content of the compound A is 15% by mass or more with respect to the total solid content of the photosensitive composition, a content of the compound β is 1% by mass or more with respect to the total solid content of the photosensitive composition, a content of the filler is 10% to 80% by mass with respect to the total solid content of the photosensitive composition, a mass ratio of the content of the filler to the content of the compound A is 0.5 or more, a mass ratio of the content of the compound β with respect to the content of the compound A is 0.7 or less, and a mass ratio of the content of the compound β to the content of the filler is 0.5 or less. In the above, the suitable content and mass ratio of the various components will be described later.

Examples of the mechanism by which the content of the carboxy group derived from the compound A is reduced by the exposure include a method by decarboxylation. The fact that the content of the carboxy group included in the compound A is reduced by the decarboxylation means that the carboxy group is eliminated as CO₂ (carbon dioxide), which does not include a case where the carboxy group is changed to a group other than the carboxy group by esterification or the like. In a case where the photosensitive layer formed of the photosensitive composition is exposed, it is presumed that a decarboxylation reaction of the carboxy group included in the compound A may occur.

Hereinafter, an estimation mechanism in which the content of the carboxy group included in the compound A is reduced by the exposure will be described in detail with reference to one example of an aspect in which the compound A includes polyacrylic acid and the compound β includes quinoline.

As shown below, a carboxy group of the polyacrylic acid and a nitrogen atom of the quinoline form a hydrogen bond in the coexistence. In a case where the quinoline is exposed, acceptability of the electron increases, and the electron is transferred from the carboxy group of the polyacrylic acid (step 1: photoexcitation). In a case where the carboxy group included in the polyacrylic acid transfers the electron to the quinoline, the carboxy group is to be unstable and to be carbon dioxide, and is eliminated (step 2: decarboxylation reaction). After the above-described decarboxylation reaction, a radical is generated in the residue of the polyacrylic acid, and a radical reaction proceeds. The radical reaction can occur between the residues of the polyacrylic acid, between the residue of the polyacrylic acid and any polymerizable compound (in the following FIGURE, M represents a structure derived from a monomer), or with a hydrogen atom in the atmosphere (step 3: polarity conversion crosslinking polymerization reaction). After the radical reaction is completed, the compound B can be regenerated and contribute to the decarboxylation process of the compound A again (step 4: regeneration of compound R

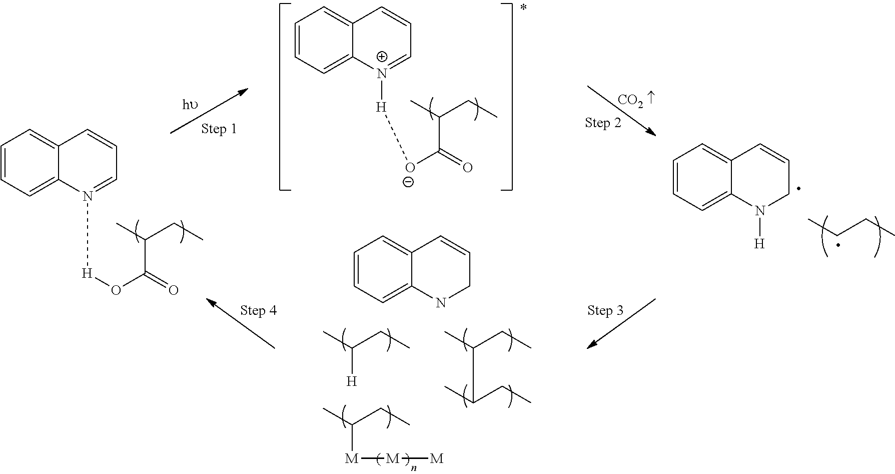

Due to the above-described mechanism, in an exposed portion of a photosensitive layer formed of the photosensitive composition, polarity changes due to reduction in the content of the carboxy group included in the compound A, and thus solubility in a developer changes. That is, in the exposed portion, the solubility in an alkali developer is decreased, and the solubility in an organic solvent developer is increased. On the other hand, in the non-exposed portion, the solubility in the developer has not changed. As a result, it is considered that the photosensitive layer has excellent pattern formability.

Hereinafter, various components which can be contained in the photosensitive composition according to the embodiment of the present invention will be described in detail.

### [Compound A]

The photosensitive composition contains a compound A.

The compound A is a compound having a carboxy group.

The compound A may be any of a low-molecular-weight compound or a high-molecular-weight compound (hereinafter, also referred to as “polymer” or “resin”), and is preferably a polymer. That is, the compound A is preferably a polymer having a carboxy group.

In a case where the compound A is a low-molecular-weight compound, a molecular weight of the compound A is preferably less than 4,500, more preferably 2,000 or less, still more preferably 1,000 or less, particularly preferably 500 or less, and most preferably 400 or less.

In a case where the compound A is a polymer, from the viewpoint of excellent formability of the photosensitive layer, a weight-average molecular weight of the compound A is preferably 4,500 or more, more preferably 10,000 or more, and still more preferably 15,000 or more. From the viewpoint of more excellent adhesiveness (laminate adhesiveness) in a case of being bonded to any base material, the upper limit thereof is preferably 100,000 or less and more preferably 50,000 or less.

A part or all of carboxy groups (—COOH) included in the compound A may or may not be anionized in the photosensitive composition. In the present specification, the notation of “carboxy group” is a concept including both an anionic carboxy group (—COO—) and a non-anionic carboxy group (—COOH).

The compound A may include a structure (hereinafter, also referred to as “specific structure S0”) in which the amount of the carboxy group included in the compound A is reduced by exposure. Hereinafter, the compound A having no specific structure S0 is also referred to as “compound Aa”, and the compound A having the specific structure S0 is also referred to as “compound Ab”. The compound Ab is preferably a polymer. That is, the compound Ab is preferably a polymer having the specific structure S0.

The fact that the compound A does not have the specific structure S0 means that the compound A may not substantially have the specific structure S0, and for example, a content of the specific structure S0 in the compound Aa may be less than 1% by mass, preferably 0% to 0.5% by mass and more preferably 0% to 0.05% by mass with respect to the total mass of the compound Aa.

A content of the specific structure S0 in the compound Ab is preferably 1% by mass or more, more preferably 1% to 50% by mass, and still more preferably 5% to 40% by mass with respect to the total mass of the compound Ab.

In a case where the compound A includes the compound Ab, a content of the compound Ab is preferably 5% to 100% by mass with respect to the total mass of the compound A.

As the above-described specific structure S0, a specific structure S1 described later is preferable.

As the compound A, a low-molecular-weight compound having a carboxy group (hereinafter, also referred to as “low-molecular-weight compound A”) or a polymer having a carboxy group (hereinafter, also referred to as “polymer A”) is preferable, and from the viewpoint that pattern formability of the photosensitive layer is more excellent and film-forming properties are more excellent, the polymer A is more preferable.

The compound A preferably includes at least one selected from the group consisting of an acrylic resin having a carboxy group, a carboxylic acid-modified epoxy (meth)acrylate resin, a modified phenol resin having a carboxy group, and a compound having a carboxy group and a bisphenol structure, and more preferably includes a carboxylic acid-modified epoxy (meth)acrylate resin.

As described above, the compound A may have the specific structure S0 (preferably, the specific structure S1). In other words, the low-molecular-weight compound A and the polymer A may have the specific structure S0 (preferably, the specific structure S1). In a case where the compound A has the specific structure S0 (preferably, the specific structure S1), the compound A is preferably the polymer A having the specific structure S0 (preferably, the specific structure S1).

### <Low-Molecular-Weight Compound A>

The low-molecular-weight compound A is not particularly limited as long as it is a low-molecular-weight compound having one or more carboxy groups.

The number of carboxy groups included in the low-molecular-weight compound A may be 1 or 2 or more, and is preferably 2 to 6.

The low-molecular-weight compound A may have a group other than the carboxy group. As the other groups, a (for example, 1 to 15, or the like) ring group or an ethylenically unsaturated group is preferable.

The ring group may be any of an aromatic ring group or an alicyclic ring group, and may have a heteroatom as a ring member atom. As the alicyclic ring group, an isocyanuric ring group is preferable.

Examples of the ethylenically unsaturated group include a (meth)acryloyl group, a vinyl group, and a styryl group, and a (meth)acryloyl group is preferable.

As the low-molecular-weight compound A, from the viewpoint of more excellent film-forming properties, a bi- or higher functional low-molecular-weight compound A having a carboxy group is preferable. The bi- or higher functional low-molecular-weight compound A means a polymerizable compound having two or more (for example, 2 to 15, or the like) ethylenically unsaturated groups in one molecule.

The low-molecular-weight compound A may further have an acid group other than the carboxy group. Examples of the acid group other than the carboxy group include a phenolic hydroxyl group, a phosphoric acid group, and a sulfonic acid group.

Examples of the low-molecular-weight compound A include tris(2-carboxyethyl) isocyanurate, 4,4′-isopropylidenediphenoxyacetic acid, and α,α,α′,α′-tetramethyl-1,3-benzenedipropionic acid.

Examples of the bi- or higher functional low-molecular-weight compound A include ARONIX (registered trademark) TO-2349 (manufactured by TOAGOSEI CO., LTD.), ARONIX M-520 (manufactured by TOAGOSEI CO., LTD.), and ARONIX M-510 (manufactured by TOAGOSEI CO., LTD.).

In addition, examples of the bi- or higher functional low-molecular-weight compound A also include a tri- or tetra-functional polymerizable compound having a carboxy group (compound obtained by introducing a carboxy group to pentaerythritol tri- and tetra-acrylate [PETA] skeleton (acid value: 80 to 120 mgKOH/g)), and a penta- or hexa-functional polymerizable compound having a carboxy group (compound obtained by introducing a carboxy group to dipentaerythritol penta- and hexa-acrylate [DPHA] skeleton (acid value: 25 to 70 mgKOH/g)). In a case where the above-described tri- or higher functional low-molecular-weight compound A having a carboxy group is used, from the viewpoint of more excellent film-forming properties, it is also preferable to use the bi- or higher functional low-molecular-weight compound A having a carboxy group in combination.

Examples of the bi- or higher functional low-molecular-weight compound A having a carboxy group include polymerizable compounds having a carboxy group, described in paragraphs 0025 to 0030 of JP2004-239942A, the contents of which are incorporated in the present specification.

### <Polymer A>

Examples of the polymer A include an acrylic resin having a carboxy group, a carboxylic acid-modified epoxy (meth)acrylate resin, and a modified phenol resin having a carboxy group.

Hereinafter, specific examples of the resin of the polymer A will be described in detail. The polymer A is not particularly limited as long as it is a resin having a carboxy group, and may have a repeating unit which can be included in each resin described later. Specifically, the polymer A may have a repeating unit represented by Formula (A), which can be included in the acrylic resin having a carboxy group.

### (Acrylic Resin Having Carboxy Group)

The acrylic resin having a carboxy group is a resin which has a carboxy group and has a repeating unit derived from (meth)acrylic acid and/or (meth)acrylic acid ester.

For example, the above-described carboxy group may be any of a carboxy group included in a repeating unit derived from (meth)acrylic acid or a carboxy group included in a repeating unit other than the repeating unit derived from (meth)acrylic acid, or may be both.

The total content of the repeating units derived from (meth)acrylic acid and (meth)acrylic acid ester is preferably 50% by mass or more, and more preferably 70% by mass or more with respect to all repeating units of the above-described acrylic resin. The upper limit thereof is preferably 100% by mass or less with respect to all repeating units of the above-described acrylic resin.

In addition, the total content of the repeating units derived from (meth)acrylic acid and (meth)acrylic acid ester is preferably 50 mol % or more, and more preferably 70 mol % or more with respect to all repeating units of the above-described acrylic resin. The upper limit thereof is preferably 100 mol % or less with respect to all repeating units of the above-described acrylic resin.

Hereinafter, repeating units which can be included in the acrylic resin having a carboxy group will be described in detail.

### —Repeating Unit Represented by Formula (A)—

The acrylic resin having a carboxy group may have a repeating unit represented by Formula (A).

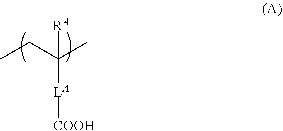

In Formula (A), R^{A} represents a hydrogen atom, a halogen atom, or an alkyl group, and L^{A} represents a single bond or a divalent linking group.

The above-described alkyl group may be linear or branched.

The number of carbon atoms in the above-described alkyl group is preferably 1 to 5 and more preferably 1.

Examples of the above-described divalent linking group include —CO—, —O—, —S—, —SO—, —S₂—, —NR^{N}— (R^{N} represents a hydrogen atom or an alkyl group having 1 to 5 carbon atoms), a hydrocarbon group (for example, an alkylene group, a cycloalkylene group, an alkenylene group, an arylene group such as a phenylene group, or the like), and a linking group obtained by combining these groups.

Examples of a monomer from which the repeating unit having a carboxy group is derived include (meth)acrylic acid, crotonic acid, itaconic acid, maleic acid, and fumaric acid, and from the viewpoint of more excellent resolution, (meth)acrylic acid is preferable. That is, the repeating unit having a carboxy group is preferably a repeating unit derived from (meth)acrylic acid, and the acrylic resin having a carboxy group preferably has the repeating unit derived from (meth)acrylic acid.

In a case where the acrylic resin having a carboxy group has a repeating unit having a carboxy group, a content of the repeating unit having a carboxy group is preferably 5 to 95 mol %, more preferably 15 to 65 mol %, still more preferably 15 to 50 mol %, and particularly preferably 15 to 40 mol % with respect to all repeating units of the above-described acrylic resin.

In a case where the acrylic resin having a carboxy group has a repeating unit having a carboxy group, a content of the repeating unit having a carboxy group is preferably 5% to 95% by mass, more preferably 15% to 65% by mass, still more preferably 15% to 50% by mass, and particularly preferably 15% to 40% by mass with respect to the total mass of the above-described acrylic resin.

### —Repeating Unit Having Polymerizable Group—

The acrylic resin having a carboxy group may have a repeating unit having a polymerizable group.

The repeating unit having a polymerizable group is a repeating unit different from the above-described repeating unit.

Examples of the polymerizable group include an ethylenically unsaturated group (for example, a (meth)acryloyl group, an allyl group, a styryl group, and the like), and a cyclic ether group (for example, an epoxy group, an oxetanyl group, and the like), and an ethylenically unsaturated group is preferable and an allyl group or a (meth)acryloyl group is more preferable.

As the repeating unit having a polymerizable group, a repeating unit represented by Formula (B) is preferable.

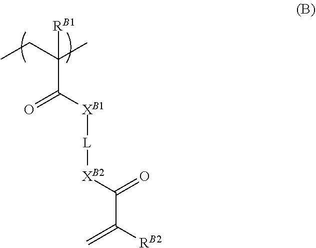

In Formula (B), X^{B1} and X^{B2} each independently represent —O— or —NR^{N}—, R^{N} represents a hydrogen atom or an alkyl group, L represents an alkylene group or an arylene group, and R^{B1} and R^{B2} each independently represent a hydrogen atom or an alkyl group.

X^{B1} and X^{B2} each independently represent —O— or —NR^{N}—. R^{N} represents a hydrogen atom or an alkyl group.

The above-described alkyl group may be linear or branched.

The number of carbon atoms in the above-described alkyl group is preferably 1 to 5.

L represents an alkylene group or an arylene group.

The above-described alkylene group may be linear or branched.

The number of carbon atoms in the above-described alkylene group is preferably 1 to 5.

The above-described arylene group may be monocyclic or polycyclic.

The number of carbon atoms in the above-described arylene group is preferably 6 to 15.

The above-described alkylene group and the above-described arylene group may have a substituent, and the substituent is preferably an acid group.

R^{B1} and R^{B2} each independently represent a hydrogen atom or an alkyl group.

The above-described alkyl group may be linear or branched.

The number of carbon atoms in the above-described alkyl group is preferably 1 to 5 and more preferably 1.

The repeating unit having a polymerizable group may be a repeating unit derived from a compound having an allyl group. Examples of the above-described repeating unit include a repeating unit derived from allyl (meth)acrylate.

In a case where the acrylic resin having a carboxy group has a repeating unit having a polymerizable group, a content of the repeating unit having a polymerizable group is preferably 3 to 60 mol %, more preferably 5 to 40 mol %, and still more preferably 10 to 30 mol % with respect to all repeating units of the above-described acrylic resin.

In a case where the acrylic resin having a carboxy group has a repeating unit having a polymerizable group, a content of the repeating unit having a polymerizable group is preferably 3% to 60% by mass, more preferably 5% to 40% by mass, and still more preferably 10% to 30% by mass with respect to the total mass of the above-described acrylic resin.

### —Repeating Unit Having Aromatic Ring—

The acrylic resin having a carboxy group may have a repeating unit having an aromatic ring.

The repeating unit having an aromatic ring is a repeating unit different from the above-described repeating units.

As the above-described aromatic ring, an aromatic hydrocarbon ring is preferable.

Examples of the repeating unit having an aromatic ring include a repeating unit derived from (meth)acrylate having an aromatic ring, and a repeating unit derived from styrene or a polymerizable styrene derivative.

Examples of the (meth)acrylate having an aromatic ring include benzyl (meth)acrylate, phenethyl (meth)acrylate, and phenoxyethyl (meth)acrylate.

Examples of the styrene and the polymerizable styrene derivative include methylstyrene, vinyltoluene, tert-butoxystyrene, acetoxystyrene, styrene dimer, and styrene trimer.

As the repeating unit having an aromatic ring, a repeating unit represented by Formula (C) is preferable.

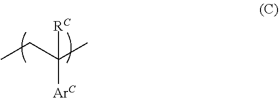

In Formula (B), R^{C} represents a hydrogen atom, a halogen atom, or an alkyl group, and Ar^{C} represents a phenyl group or a naphthyl group.

The above-described alkyl group may be linear or branched.

The number of carbon atoms in the above-described alkyl group is preferably 1 to 5 and more preferably 1.

The above-described phenyl group and the above-described naphthyl group may have a substituent, and examples of the substituent include an alkyl group, an alkoxy group, an aryl group, a halogen atom, and a hydroxy group.

Ar^{C} is preferably a phenyl group.

Examples of the repeating unit having an aromatic ring include the following repeating units.

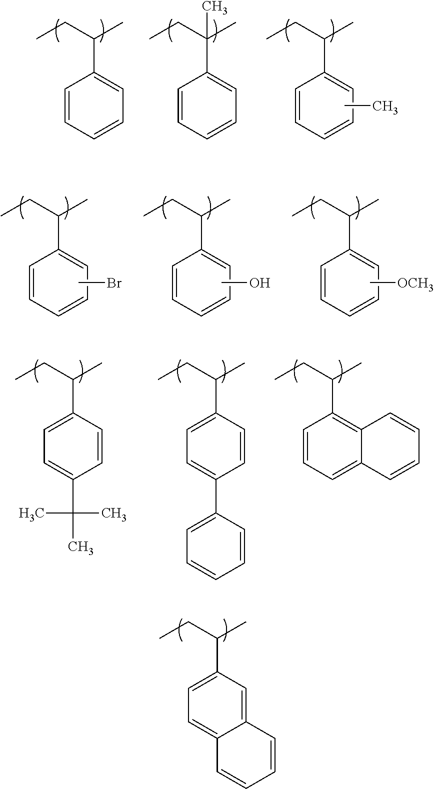

In a case where the acrylic resin having a carboxy group has a repeating unit having an aromatic ring, a content of the repeating unit having an aromatic ring is preferably 5 to 90 mol %, more preferably 15 to 85 mol %, still more preferably 30 to 80 mol %, and particularly preferably 50 to 80 mol % with respect to all repeating units of the above-described acrylic resin.

In a case where the acrylic resin having a carboxy group has a repeating unit having an aromatic ring, a content of the repeating unit having an aromatic ring is preferably 5% to 90% by mass, more preferably 15% to 85% by mass, still more preferably 30% to 85% by mass, and particularly preferably 50% to 85% by mass with respect to the total mass of the above-described acrylic resin.

### —Repeating Unit Having Alicyclic Ring—

The acrylic resin having a carboxy group may have a repeating unit having an alicyclic ring.

The repeating unit having an alicyclic ring is a repeating unit different from the above-described repeating units.

The alicyclic ring may be a monocycle or a polycycle.

Examples of the alicyclic ring include a dicyclopentanyl ring, a dicyclopentenyl ring, an isobornyl ring, an adamantane ring, and a cyclohexyl ring.

Examples of a monomer from which the repeating unit having an alicyclic ring is derived include dicyclopentanyl (meth)acrylate, dicyclopentenyl (meth)acrylate, isobornyl (meth)acrylate, adamantyl (meth)acrylate, and cyclohexyl (meth)acrylate.

In a case where the acrylic resin having a carboxy group has a repeating unit having an alicyclic ring, a content of the repeating unit having an alicyclic ring is preferably 5 to 90 mol %, more preferably 15 to 85 mol %, still more preferably 30 to 80 mol %, and particularly preferably 50 to 80 mol % with respect to all repeating units of the above-described acrylic resin.

In a case where the acrylic resin having a carboxy group has a repeating unit having an alicyclic ring, a content of the repeating unit having an alicyclic ring is preferably 5% to 90% by mass, more preferably 15% to 85% by mass, still more preferably 30% to 85% by mass, and particularly preferably 50% to 85% by mass with respect to the total mass of the above-described acrylic resin.

—Repeating Unit Derived from (Meth)Acrylic Acid Alkyl Ester—

As the repeating unit derived from (meth)acrylic acid ester, which can be included in the acrylic resin having a carboxy group, a repeating unit derived from (meth)acrylic acid alkyl ester is preferable.

The repeating unit derived from (meth)acrylic acid alkyl ester is a repeating unit different from the above-described repeating units.

An alkyl group in the alkyl (meth)acrylate is preferably linear or branched.

The number of carbon atoms in the alkyl group is preferably 1 to 50, more preferably 1 to 10, and still more preferably 1 to 6. The above-described alkyl group may further have a substituent such as a hydroxy group.

Examples of the (meth)acrylic acid alkyl ester include methyl (meth)acrylate.

In a case where the acrylic resin having a carboxy group has a repeating unit derived from (meth)acrylic acid alkyl ester, a content of the repeating unit derived from (meth)acrylic acid alkyl ester is preferably 1 to 80 mol %, and more preferably 50 to 80 mol % with respect to all repeating units of the above-described acrylic resin.

In a case where the acrylic resin having a carboxy group has a repeating unit derived from (meth)acrylic acid alkyl ester, a content of the repeating unit derived from (meth)acrylic acid alkyl ester is preferably 1% to 80% by mass, and more preferably 50% to 80% by mass with respect to the total mass of the above-described acrylic resin.

### —Repeating Unit Having Specific Structure S0—

The acrylic resin having a carboxy group may have a repeating unit having the specific structure S0 (preferably, the specific structure S1).

The repeating unit having the specific structure S0 is a repeating unit different from the above-described repeating units.

The specific structure S0 and the specific structure S1 have the same meaning as the specific structure S0 and the specific structure S1 of the compound β described later, and suitable aspects thereof are also the same.

In the repeating unit having the specific structure S0 (preferably, the specific structure S1), the specific structure S0 (preferably, the specific structure S1) may be present in a main chain or may be present in a side chain, and is preferably present in the side chain. In a case where the specific structure S0 (preferably, the specific structure S1) is present in the side chain, the specific structure S0 (preferably, the specific structure S1) is bonded to a polymer main chain through a single bond or a linking group.

Examples of the repeating unit having the specific structure S0 (preferably, the specific structure S1) include a repeating unit derived from a monomer having a heteroaromatic ring (for example, a vinyl heteroaromatic ring such as vinylpyridine and vinyl(iso)quinoline, a (meth)acrylate monomer having a heteroaromatic ring, or the like).

Examples of the repeating unit having the specific structure S0 (preferably, the specific structure S1) include the following repeating units.

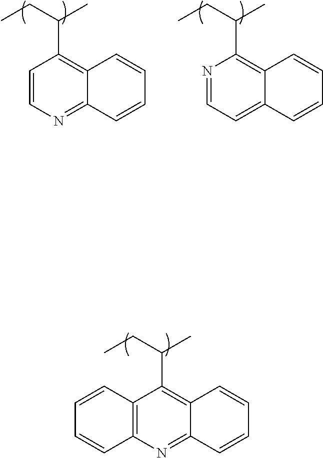

In a case where the acrylic resin having a carboxy group has a repeating unit having the specific structure S0 (preferably, the specific structure S1), a content of the repeating unit having the specific structure S0 (preferably, the specific structure S1) is preferably 3 to 75 mol %, more preferably 5 to 60 mol %, and still more preferably 10 to 50 mol % with respect to all repeating units of the above-described acrylic resin.

In a case where the acrylic resin having a carboxy group has a repeating unit having the specific structure S0 (preferably, the specific structure S1), a content of the repeating unit having the specific structure S0 (preferably, the specific structure S1) is preferably 3% to 75% by mass, more preferably 5% to 60% by mass, and still more preferably 10% to 50% by mass with respect to the total mass of the above-described acrylic resin.

The acrylic resin having a carboxy group may have other repeating units in addition to the above-described repeating units. The other repeating units are not particularly limited.

### (Carboxylic Acid-Modified Epoxy (Meth)Acrylate Resin)

The carboxylic acid-modified epoxy (meth)acrylate resin is a resin obtained by introducing a (meth)acryloyl group into a carboxylic acid having a (meth)acryloyl group by ring-opening addition of a carboxylic group of the carboxylic acid to an epoxy group of an epoxy resin as a matrix, and further introducing a carboxy group by addition of a polybasic carboxylic acid or an anhydride thereof to at least one hydroxyl group generated by the ring-opening of the epoxy group.

That is, the carboxylic acid-modified epoxy (meth)acrylate resin is a resin having a carboxy group.

The carboxylic acid having a (meth)acryloyl group is a compound having one or more carboxy groups and one or more (meth)acryloyl groups.

The above-described number of carboxy groups is preferably 1 to 3, and more preferably 1.

The above-described number of (meth)acryloyl groups is preferably 1 to 3, and more preferably 1.

Examples of the carboxylic acid having a (meth)acryloyl group include acrylic acid and methacrylic acid.

The epoxy resin as a matrix preferably has a ring such as an aromatic ring and an alicyclic ring, more preferably has an aromatic ring, and still more preferably has an aromatic hydrocarbon ring.

The aromatic ring may be a monocycle or a polycycle.

The number of carbon atoms in the aromatic ring is preferably 6 to 30 and more preferably 6 to 15.

Examples of the aromatic ring include a benzene ring, a biphenyl ring, a naphthalene ring, and an anthracene ring.

The aromatic ring may further have a substituent. Examples of the substituent include a hydroxyl group and an alkyl group.

Examples of the epoxy resin as a matrix include an epoxy resin having a biphenyl structure, a bisphenol A-type epoxy resin, a bisphenol F-type epoxy resin, a phenol novolac-type epoxy resin, and a cresol novolac-type epoxy resin.

Examples of the polybasic carboxylic acid or an anhydride thereof include maleic acid, maleic acid anhydride, succinic acid, succinic acid anhydride, tetrahydrophthalic acid, and tetrahydrophthalic acid anhydride.

The carboxylic acid-modified epoxy (meth)acrylate resin preferably has a group represented by Formula (D).

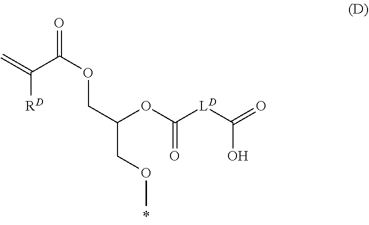

In Formula (D), * represents a bonding position, L^{D} represents a single bond or a divalent linking group, and R^{D} represents a hydrogen atom or an alkyl group.

L^{D} represents a single bond or a divalent linking group.

Examples of the divalent linking group include —CO—, —O—, —S—, —SO—, —SO₂—, —NR^{N}— (R^{N} represents a hydrogen atom or an alkyl group having 1 to 5 carbon atoms), a hydrocarbon group (for example, an alkylene group, a cycloalkylene group, an alkenylene group, an arylene group such as a phenylene group, or the like), and a linking group obtained by combining these groups.

As the divalent linking group, a hydrocarbon group is preferable, and a hydrocarbon group having 1 to 10 carbon atoms is more preferable.

R^{D} represents a hydrogen atom or an alkyl group.

The above-described alkyl group may be linear or branched.

The number of carbon atoms in the above-described alkyl group is preferably 1 to 5 and more preferably 1.

The carboxylic acid-modified epoxy (meth)acrylate resin may have the above-described repeating unit which can be included in the acrylic resin having a carboxy group.

Examples of the carboxylic acid-modified epoxy (meth)acrylate resin include KAYARAD CCR series (for example, 1171 and the like), ZAR series (for example, 1494H, 2001H, 2051H, and the like), ZFR series (for example, 1491H, 1569H, and the like), ZCR series (for example, 1569H, 1797H, 1798H, 1761H, and the like), and UXE series (for example, 3000 and the like) (all manufactured by Nippon Kayaku Co., Ltd.).

### (Modified Phenol Resin Having Carboxy Group)

The modified phenol resin having a carboxy group is a resin in which a compound having a carboxy group is added to a phenolic hydroxyl group included in a phenol resin as a matrix to introduce a carboxy group.

The modified phenol resin having a carboxy group is a resin different from the above-described various components.

The number of carboxy groups included in the compound having a carboxy group is 1 or more, and preferably 1 to 3.

The carboxy group included in the compound having a carboxy group may be a carboxy group protected by a protective group, which is generated by a deprotection reaction. Specifically, the compound having a carboxy group may be a compound having a methyl ester group in which the carboxy group is protected by a methyl group.

The compound having a carboxy group may have a group other than the carboxy group. Examples of other groups include a functional group which can react with a phenolic hydroxyl group such as an acid group other than the carboxy group (for example, a phenolic hydroxyl group, a phosphoric acid group, a sulfonic acid group, and the like) and a halogen atom (for example, a chlorine atom, an iodine atom, and the like).

The compound having a carboxy group may be any of a low-molecular-weight compound or a high-molecular-weight compound (polymer), and a low-molecular-weight compound is preferable. Specifically, a molecular weight of the compound having a carboxy group is preferably less than 5,000, more preferably 2,000 or less, and still more preferably 1,000 or less. The lower limit thereof is preferably 30 or more.

Examples of the compound having a carboxy group include methyl acetate, methyl chloroacetate, methyl 3-chloropropionate, and methyl 2-chloropropionate.

Examples of the phenol resin as a matrix include a phenol novolac resin, a cresol novolac resin, a biphenyl aralkyl-type phenol resin, a naphthol aralkyl resin, and a naphthol novolac resin.

The modified phenol resin having a carboxy group preferably has a group represented by Formula (E), and more preferably has a repeating unit represented by Formula (E1).

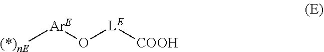

In Formula (E), Ar^{E} represents an aromatic ring, L^{E} represents a divalent linking group, nE represents an integer of 1 or more, and * represents a bonding position.

Ar^{E} represents an aromatic ring.

Examples of the aromatic ring include the aromatic ring which can be included in the above-described epoxy resin.

L^{E} represents a divalent linking group.

Examples of the divalent linking group include the divalent linking group represented by LD.

As the divalent linking group, a hydrocarbon group is preferable, and an alkylene group is more preferable.

nE represents an integer of 1 or more.

nE is preferably an integer of 1 to 5 and more preferably an integer of 1 to 3.

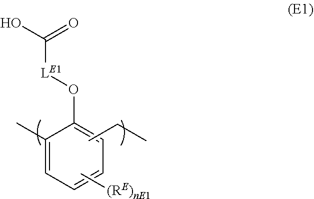

In Formula (E1), R^{E} represents a substituent, L^{E1} represents a divalent linking group, and nE1 represents an integer of 0 to 3.

R^{E} represents a substituent.

The substituent represented by R^{E} is preferably an alkyl group or a hydroxyl group. The above-described alkyl group may be linear or branched.

The number of carbon atoms in the above-described alkyl group is preferably 1 to 10, more preferably 1 to 5, and still more preferably 1 to 3.

Examples of the above-described alkyl group include a methyl group, an ethyl group, a propyl group, and a butyl group.

In a case of a plurality of R^{E}'s, R^{E}'s may be the same or different from each other.

L^{E1} represents a divalent linking group.

L^{E1} has the same meaning as L^{E} described above, and a suitable aspect thereof is also the same.

nE1 represents an integer of 0 to 3.

nE1 is preferably an integer of 0 to 2.

The modified phenol resin having a carboxy group may have the repeating unit which can be included in the above-described acrylic resin having a carboxy group.

### <Compound Having Carboxy Group and Bisphenol Structure>

The compound having a carboxy group and a bisphenol structure is a compound having one or more carboxy groups and one or more bisphenol structures in the molecule.

The compound having a carboxy group and a bisphenol structure is a compound different from the above-described various components.

The above-described compound having a carboxy group and a bisphenol structure may be any of a low-molecular-weight compound or a high-molecular-weight compound (polymer), and is preferably a high-molecular-weight compound.

Suitable molecular weights of the low-molecular-weight compound and the high-molecular-weight compound are as described above.

Examples of the bisphenol structure include a structure derived from bisphenol A, a structure derived from bisphenol AP, a structure derived from bisphenol AF, a structure derived from bisphenol B, a structure derived from bisphenol BP, a structure derived from bisphenol C, a structure derived from bisphenol E, a structure derived from bisphenol F, a structure derived from bisphenol G, a structure derived from bisphenol M, a structure derived from bisphenol S, and a structure derived from bisphenol P.

The compound having a carboxy group and a bisphenol structure may have a group other than the carboxy group. Examples of other groups include an acid group other than the carboxy group (for example, a phenolic hydroxyl group, a phosphoric acid group, a sulfonic acid group, and the like) and a halogen atom (for example, a chlorine atom, an iodine atom, and the like).

The compound having a carboxy group and a bisphenol structure may have the repeating unit which can be included in the above-described acrylic resin having a carboxy group.

From the viewpoint of developability, an acid value of the compound A is preferably 10 to 600 mgKOH/g and more preferably 30 to 500 mgKOH/g.

The above-described acid value can be measured in accordance with JIS K 0070 (1992).

The compound A may be used alone or in combination of two or more kinds thereof.

In a case where the photosensitive composition contains the polymer A, a content of the polymer A is preferably 75% to 100% by mass, more preferably 85% to 100% by mass, still more preferably 90% to 100% by mass, and particularly preferably 95% to 100% by mass with respect to the total mass of the compound A.

In a case where the photosensitive composition contains the low-molecular-weight compound A, a content of the low-molecular-weight compound A is preferably 0% to 25% by mass, more preferably 0% to 10% by mass, and still more preferably 0% to 5% by mass with respect to the total mass of the compound A.

The lower limit of the content of the compound A is usually 1% by mass or more, preferably 15% by mass or more, more preferably 20% by mass or more, still more preferably 30% by mass or more, particularly preferably 45% by mass or more, and most preferably 50% by mass or more with respect to the total solid content of the photosensitive composition. The upper limit thereof is preferably less than 100% by mass, more preferably 99% by mass or less, still more preferably 98% by mass or less, and particularly preferably 95% by mass or less with respect to the total solid content of the photosensitive composition.

In the photosensitive composition of the embodiment X-1-a1, the content of the compound A is preferably 45% to 98% by mass and more preferably 50% to 95% by mass with respect to the total solid content of the photosensitive composition.

### [Compound β]

The photosensitive composition contains a compound β.

The compound β is a compound having a structure (specific structure S0) in which an amount of the carboxy group included in the compound A is reduced by exposure.

The specific structure S0 is a structure which exhibits an action of reducing the amount of the carboxy group included in the compound A in a case of being exposed. The specific structure S0 is preferably a structure which transitions from a ground state to an excited state by the exposure, and exhibits the action of reducing the carboxy group included in the compound A in the excited state.

Examples of the specific structure S0 include a structure capable of accepting an electron from the carboxy group included in the compound Ain a photoexcited state (hereinafter, also referred to as “specific structure S1”).

The specific structure S0 included in the compound β may be an overall structure constituting the entire compound β or a partial structure constituting a part of the compound β.

The compound β may be either a low-molecular-weight compound or a high-molecular-weight compound, and is preferably a low-molecular-weight compound.

In a case where the compound β is a low-molecular-weight compound, a molecular weight of the compound β is preferably less than 5,000, more preferably less than 1,000, still more preferably 65 to 300, and particularly preferably 75 to 250.

As the specific structure S0, a structure (specific structure S1) capable of accepting an electron from the carboxy group included in the compound Ain a photoexcited state is preferable. That is, the compound β is preferably a compound B having the structure (specific structure S1) capable of accepting an electron from the carboxy group included in the compound A in a photoexcited state. According to the compound B, it is considered that the carboxy group included in the compound A can be eliminated (decarboxylated) as CO₂.

Hereinafter, the compound β (preferably, the compound B) will be described in detail.

From the viewpoint that the pattern formability is more excellent, the compound β (preferably, the compound B) is preferably an aromatic compound having an aromatic ring as the specific structure S0. That is, the specific structure S0 is preferably an aromatic ring, and more preferably a heteroaromatic ring as described later.

The aromatic compound is a compound having one or more aromatic rings.

Only one aromatic ring may be present in the compound β (preferably, the compound B), or a plurality of aromatic rings may be present therein. In a case where a plurality of aromatic rings is present, for example, the above-described aromatic rings may be present in the side chain or the like of the resin.

In the compound β (preferably, the compound B), the aromatic ring can be used as the structure (specific structure S0 (preferably, specific structure S1)) in which the amount of the carboxy group included in the compound A is reduced by exposure.

The above-described aromatic ring may be monocyclic or polycyclic, and is preferably polycyclic. For example, the polycyclic aromatic ring is an aromatic ring in which a plurality of (for example, 2 to 5, or the like) aromatic ring structures is fused, and at least one of the plurality of aromatic ring structures preferably has a heteroatom as a ring member atom.

The above-described aromatic ring may be a heteroaromatic ring, and a heteroaromatic ring having 1 or more (for example, 1 to 4, or the like) heteroatoms (for example, nitrogen atom, oxygen atom, sulfur atom, and the like) as a ring member atom is preferable; and a heteroaromatic ring having 1 or more (for example, 1 to 4, or the like) nitrogen atoms as a ring member atom is more preferable.

The number of ring member atoms in the above-described aromatic ring is preferably 5 to 15.

From the viewpoint that a molar absorption coefficient at a wavelength of 365 nm is higher, the above-described aromatic ring of the compound β (preferably, the compound B) is preferably a polycycle (polycyclic aromatic ring). The number of monocyclic aromatic rings in the polycyclic aromatic ring (the number of fused rings) is preferably 2 or more, and from the viewpoint that the molar absorption coefficient at a wavelength of 365 nm is higher, it is more preferable to be 3 or more. The upper limit thereof may be 6 or less.

In addition, it is also preferable that the above-described polycyclic aromatic ring has a heteroatom (for example, a nitrogen atom, an oxygen atom, a sulfur atom, and the like) as a ring member atom (in other words, it is a polycyclic heteroaromatic ring).

Examples of the above-described aromatic ring included in the compound β (preferably, the compound B) include monocyclic aromatic rings such as a pyridine ring, a pyrazine ring, a pyrimidine ring, and a triazine ring; aromatic rings in which two rings are fused, such as a quinoline ring, an isoquinoline ring, a quinoxaline ring, and a quinazoline ring; and aromatic rings in which three rings are fused, such as an acridine ring, a benzo[f]quinoline ring, a benzo[h]quinoline ring, a phenanthridine ring (benzo[c]quinoline ring), a benzo[h]isoquinoline ring, a phenanthroline ring, and a phenazine ring.

The above-described aromatic ring may have one or more (for example, 1 to 5) substituents, and examples of the substituent include an alkyl group, an aryl group, a halogen atom, an acyl group, an alkoxycarbonyl group, an arylcarbonyl group, a carbamoyl group, a hydroxy group, a cyano group, and a nitro group. In addition, in a case where the above-described aromatic ring has two or more substituents, a plurality of substituents may be bonded to each other to form a non-aromatic ring.

In addition, it is also preferable that the above-described aromatic ring is directly bonded to a carbonyl group to form an aromatic carbonyl group in the compound β (preferably, the compound B). It is also preferable that a plurality of aromatic rings is bonded through a carbonyl group.

It is also preferable that the above-described aromatic ring is bonded to an imide group to form an aromatic imide group in the compound β (preferably, the compound B). The imide group in the aromatic imide group may or may not form an imide ring together with the aromatic ring.

In a case where a plurality of aromatic rings (for example, 2 to 5) forms a series of aromatic ring structures bonded with a structure selected from the group consisting of a single bond, a carbonyl group, and a multiple bond (for example, a vinylene group which may have a substituent, —C≡C—, —N═N—, and the like), the entire series of aromatic ring structures is regarded as one specific structure.

In addition, it is preferable that one or more of aromatic rings constituting the series of aromatic ring structures are the above-described heteroaromatic rings.

From the viewpoint that the pattern formability is more excellent, the compound β (preferably, the compound B) is preferably a compound satisfying one or more (for example, one to four, and the like) of the requirement (1) to the requirement (4), more preferably a compound satisfying at least one of the requirement (1) or the requirement (2), and still more preferably a compound satisfying at least the requirement (1) and the requirement (2) (that is, a polycyclic heteroaromatic ring). It is preferable that the heteroatom included in the heteroaromatic ring is at least a nitrogen atom.

Requirement (1): having a polycyclic aromatic ring

Requirement (2): having a heteroaromatic ring

Requirement (3): having an aromatic carbonyl group

Requirement (4): having an aromatic imide group

Examples of the compound β (preferably, the compound B) include monocyclic aromatic compounds such as pyridine, pyrazine, pyrimidine, and triazine; compounds in which two rings are fused to form an aromatic ring, such as quinoline, isoquinoline, quinoxaline, and quinazoline; and compounds in which three or more rings are fused to form an aromatic ring, such as acridine, benzo[f]quinoline, benzo[h]quinoline, phenanthridine, benzo[h]isoquinoline, phenanthroline, and phenazine.

These compounds may further have a substituent. As the above-described substituent, an alkyl group, an aryl group, a halogen atom, an acyl group, an alkoxycarbonyl group, an arylcarbonyl group, a carbamoyl group, a hydroxy group, a cyano group, or a nitro group is preferable.

From the viewpoint that the molar absorption coefficient at a wavelength of 365 nm is higher and sensitivity at the wavelength of 365 nm is excellent, the compound β (preferably, the compound B) is preferably one or more selected from the group consisting of acridine, benzo[f]quinoline, benzo[h]quinoline, phenanthridine, benzo[h]isoquinoline, phenanthroline, and phenazine. These compounds may further have a substituent, and as the substituent, an alkyl group, an aryl group, a halogen atom, an acyl group, an alkoxycarbonyl group, an arylcarbonyl group, a carbamoyl group, a hydroxy group, a cyano group, or a nitro group is preferable.

In a case where the compound β (preferably, the compound B) is a polymer, the polymer may be a polymer in which the specific structure is bonded to a polymer main chain through a single bond or a linking group.

The compound β (preferably, the compound B) which is a polymer is obtained, for example, by polymerizing a monomer having a polycyclic heteroaromatic ring (specifically, a (meth)acrylate monomer having a vinyl polycyclic heteroaromatic ring and/or a specific structure (preferably, a polycyclic heteroaromatic ring)). If necessary, it maybe copolymerized with another monomer.

From the viewpoint that the pattern formability is more excellent, a molar absorption coefficient of the compound β (preferably, the compound B) at a wavelength of 365 nm is preferably 100 L/(mol cm) or more, more preferably 500 L/(mol cm) or more, still more preferably more than 1,000 L/(mol cm), and particularly preferably 4,000 L/(mol cm) or more. The upper limit of the above-described molar absorption coefficient may be 20,000 L/(mol cm) or less.

The above-described molar absorption coefficient at a wavelength of 365 nm is a molar absorption coefficient measured by dissolving the compound β (preferably, the compound B) in acetonitrile. In a case where the compound β (preferably, the compound B) is insoluble in acetonitrile, a solvent for dissolving the compound β (preferably, the compound B) may be appropriately changed.

The fact that the molar absorption coefficient ε of the compound β (preferably, the compound B) is within the above-described range is particularly advantageous in a case where the photosensitive layer is exposed through a temporary support (preferably, a PET film). That is, since the molar absorption coefficient is moderately low, even in a case of being exposed through the temporary support, generation of bubbles due to the decarboxylation can be controlled, and deterioration of the pattern shape can be prevented.

Examples of the compound having a high molar absorption coefficient at a wavelength of 365 nm include a compound in which three or more aromatic rings are fused to form an aromatic ring. Examples of the compound in which three or more aromatic rings are fused to form an aromatic ring include the above-described compounds.

Examples of the compound β (preferably, the compound B) include 5,6,7,8-tetrahydroquinoline, 4-acetylpyridine, 4-benzoylpyridine, quinoline, benzo[f]quinoline, benzo[h]quinoline, isoquinoline, benzo[h]isoquinoline, 1-methylisoquinoline, 1-phenylisoquinoline, acridine, 9-methylacridine, phenanthridine, phenanthroline, and phenazine.

The compound β preferably includes at least one selected from the group consisting of acridine, 9-methylacridine, and 9-phenylacridine.

The compound β (preferably, the compound B) may be used alone or in combination of two or more kinds thereof.

From the viewpoint that the pattern formability is more excellent, a lower limit of a content of the compound β (preferably, the compound B) is preferably 0.1% by mass or more and more preferably 1% by mass or more with respect to the total solid content of the photosensitive composition. The upper limit thereof is preferably 80% by mass or less, more preferably 60% by mass or less, still more preferably 30% by mass or less, and particularly preferably 20% by mass or less with respect to the total solid content of the photosensitive composition.

In the photosensitive composition of the embodiment X-1-a1, the content of the compound β (preferably, the compound B) is preferably 1% to 30% by mass and more preferably 1% to 20% by mass with respect to the total solid content of the photosensitive composition.

From the viewpoint that the pattern formability is more excellent, the total number of specific structures S0 (preferably, specific structures S1) included in the compound β (preferably, the compound B) is preferably 1 mol % or more, more preferably 3 mol % or more, still more preferably 5 mol % or more, and particularly preferably 10 mol % or more with respect to the total number of carboxy groups included in the compound A.

From the viewpoint of film quality of the film to be obtained, the upper limit of the total number of specific structures S0 (preferably, specific structures S1) in the compound β (preferably, the compound B) is preferably 200 mol % or less, more preferably 100 mol % or less, and still more preferably 80 mol % or less with respect to the total number of carboxy groups included in the compound A.

The mass ratio of the content of the compound β to the content of the compound A is preferably 0.7 or less and more preferably 0.5 or less. The upper limit thereof is not particularly limited, but is preferably 0.005 or more.

### [Filler]

The photosensitive composition contains a filler.

Examples of the filler include an organic filler and an inorganic filler, and an inorganic filler is preferable.

Examples of the filler include silicon dioxide (for example, silica or the like); silicate such as kaolinite, kaolin clay, calcined clay, talc, and undoped glass; and alumina, barium sulfate, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, calcium zirconate, zirconium phosphate, cordierite, zirconium tungstate, and manganese nitride.

The filler preferably includes at least one selected from the group consisting of silicon dioxide, boron nitride, barium sulfate, and silicate, and more preferably includes silicon dioxide.

A shape of the filler may be a spherical shape or a non-spherical shape (for example, a crushed shape and a fibrous shape), and a spherical shape is preferable.

The filler may be subjected to a surface treatment. Examples of the surface treatment include a treatment of introducing a functional group and a treatment using a known surface modifier.

Examples of the surface modifier include a silane coupling agent, a titanate-based coupling agent, and a silazane compound.

Examples of the filler include SC-2050 MB (manufactured by Admatechs Co., Ltd., silicon dioxide, epoxy silane surface-treated product, concentration of solid contents of 70% by mass of methyl ethyl ketone (MEK) slurry), S0-C2 (manufactured by Admatechs Co., Ltd., silicon dioxide), Sea Foster KE-S30 (manufactured by Nippon Shokubai Co., Ltd., silicon dioxide, not surface-treated, concentration of solid contents of 100% by mass), NHIM-3N (manufactured by TOKUYAMA CORPORATION, silicon dioxide, trimethylsilyl surface-treated, concentration of solid contents of 100% by mass), YA050C-MJE (manufactured by Admatechs Co., Ltd., silicon dioxide, methacrylic surface-treated product, concentration of solid contents of 50% by mass MEK slurry), MEK-EC-2430Z (manufactured by NISSAN CHEMICAL CORPORATION, epoxy silane surface-treated, concentration of solid contents of 30% by mass), barium sulfate (manufactured by SOLVAY SPECIALTY CHEMICALS JAPAN, no surface treatment, concentration of solid contents of 100% by mass), AZ FILLER (manufactured by AGC Inc., no surface treatment, concentration of solid contents of 100% by mass), spherical alumina (manufactured by SHOWA DENKO K.K., CB-P02 (average particle diameter: 2 μm), CB-P05 (average particle diameter: 4 μm)), talc (manufactured by RINKA CORPORATION, MW WHS-T (average particle diameter: 4.75 m), KHP-25 (average particle diameter: 4.75 μm)), clay (manufactured by Takehara Chemical Industrial Co., Ltd., kaolin clay RC-1 (average particle diameter: 0.4 m)), mica powder (manufactured by Yamaguchi Mica Co., Ltd., A-11 (average particle diameter: 3 m)), and boron nitride (manufactured by SHOWA DENKO K.K., UHP-S1 (average particle diameter: 0.5 m)).

Examples of the filler also include those described in paragraphs 0032 to 0042 of JP2019-104941A.

An average primary particle diameter of the filler is preferably 1 to 5,000 nm, more preferably 5 to 1,000 nm, and still more preferably 10 to 300 nm.

The average primary particle diameter can be measured using, for example, a dynamic scattering method analysis apparatus.

A refractive index of the filler is preferably 0.5 to 3.0 and more preferably 1.2 to 1.8.

The refractive index can be measured by the above-described method.

The filler may be used alone or in combination of two or more kinds thereof.

A content of the filler is usually 1% by mass or more, preferably 10% to 90% by mass, more preferably 10% to 80% by mass, and still more preferably 35% to 70% by mass with respect to the total solid content of the photosensitive composition.

The mass ratio of the content of the filler to the content of the compound A is preferably 0.5 or more, more preferably 1.0 or more, and still more preferably 1.5 or more. The upper limit thereof is not particularly limited, but is preferably 10.0 or less.

The mass ratio of the content of the compound β to the content of the filler is preferably 0.5 or less, more preferably 0.3 or less, and still more preferably 0.1 or less. The upper limit thereof is not particularly limited, but is preferably 0.0005 or more.

### [Epoxy Compound]

From the viewpoint that the effect of the present invention is more excellent, the photosensitive composition preferably contains an epoxy compound.

The epoxy compound is a compound having an epoxy group, and is a compound different from the above-described various components.

The epoxy compound may be either a low-molecular-weight compound or a high-molecular-weight compound, and is preferably a high-molecular-weight compound.

In a case where the epoxy compound is a low-molecular-weight compound, a molecular weight of the epoxy compound is preferably less than 4,500, more preferably 2,000 or less, and still more preferably 1,000 or less.

In a case where the epoxy compound is a high-molecular-weight compound, a molecular weight of the epoxy compound is preferably 4,500 or more, more preferably 10,000 or more, and still more preferably 15,000 or more. The upper limit thereof is preferably 100,000 or less and more preferably 50,000 or less.

The epoxy compound may be a compound having one or more epoxy groups in one molecule, and preferably has two or more epoxy groups. The upper limit thereof may be 100 or less.

The epoxy compound may have a group other than an epoxy group, and as other groups, an aromatic ring group is preferable.

The aromatic ring group may be monocyclic or polycyclic. The aromatic ring group may further have a substituent.

The number of carbon atoms in the aromatic ring group is preferably 6 to 30 and more preferably 6 to 12.

Examples of the aromatic ring group include a phenyl group, a naphthyl group, an anthryl group, a pyrenyl group, a phenanthrenyl group, a methylphenyl group, a dimethylphenyl group, a biphenyl group, and a fluorenyl group; and a phenyl group or a biphenyl group is preferable.

Examples of the epoxy compound include TETRAD-X (manufactured by Mitsubishi Gas Chemical Company, Inc.), jER (registered trademark) epoxy resin (for example, 828, 828EL, and the like; manufactured by Mitsubishi Chemical Corporation), EPICLON series (registered trademark) (for example, N-770 and the like; manufactured by DIC Corporation), TECHMORE VG3101L (manufactured by PRINTTECK Co., Ltd.), and NC-3000 (manufactured by Nippon Kayaku Co., Ltd.).

The epoxy compound preferably includes at least one selected from the group consisting of a bisphenol A-type epoxy resin, a bisphenol F-type epoxy resin, a biphenyl-type epoxy resin, a phenol novolac-type epoxy resin, a cresol novolac-type epoxy resin, and a urethane epoxy-type epoxy resin, and more preferably includes at least one selected from the group consisting of a bisphenol A-type epoxy resin, a phenol novolac-type epoxy resin, and a biphenyl-type epoxy resin.

An epoxy value of the epoxy compound is preferably 50 to 500 g/eq and more preferably 90 to 290 g/eq.

The epoxy value can be calculated from, for example, a chemical structure of the epoxy compound. Specifically, the epoxy value can be calculated by dividing the molecular weight of the epoxy compound by the number of epoxy groups in one molecule.

The epoxy compound may be used alone or in combination of two or more kinds thereof.

In a case where the photosensitive composition contains an epoxy compound, a content of the epoxy compound is preferably 1% to 40% by mass and more preferably 1% to 20% by mass with respect to the total solid content of the photosensitive composition.

### [Surfactant]

The photosensitive composition may contain a surfactant.

The surfactant is a compound different from the above-described various components.

Examples of the surfactant include an anionic surfactant, a cationic surfactant, a nonionic surfactant, and an amphoteric surfactant, and a nonionic surfactant is preferable.

Examples of the nonionic surfactant include polyoxyethylene higher alkyl ethers, polyoxyethylene higher alkylphenyl ethers, polyoxyethylene glycol higher fatty acid diesters, silicone-based surfactants, and fluorine-based surfactants.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters; PLURONIC L10, L31, L61, L62, 10R5, 17R2, and 25R2 (all of which are manufactured by BASF SE); TETRONIC 304, 701, 704, 901, 904, and 150R1 (all of which are manufactured by BASF SE); SOLSPERSE 20000 (all of which are manufactured by Lubrizol Corporation); NCW-101, NCW-1001, and NCW-1002 (all of which are manufactured by FUJIFILM Wako Pure Chemical Corporation); PIONIN D-6112, D-6112-W, and D-6315 (all of which are manufactured by Takemoto Oil&Fat Co., Ltd.); and OLFINE E1010 and SURFYNOL 104, 400, and 440 (all of which are manufactured by Nissin Chemical Co., Ltd.).

Examples of the silicone-based surfactant include a linear polymer consisting of a siloxane bond and a modified siloxane polymer with an organic group introduced in the side chain or the terminal.

Examples of the fluorine-based surfactant include: MEGAFACE F-171, F-172, F-173, F-176, F-177, F-141, F-142, F-143, F-144, F-437, F-475, F-477, F-479, F-482, F-551, F-551-A, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, R5-43, TF-1956, RS-90, R-94, RS-101, RS-102, RS-718K, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED); and U-120E (Uni-chem Co., Ltd.).

In addition, as the fluorine-based surfactant, a polymer of a fluorine atom-containing vinyl ether compound having a fluorinated alkyl group or a fluorinated alkylene ether group, and a hydrophilic vinyl ether compound is also preferable.

In addition, as the fluorine-based surfactant, a block polymer is also preferable.

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is also preferable.

Examples of the surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.); X-22-4952, X-22-4272, X-22-6266, KF-351A, K354L, KF-355A, KF-945, KF-640, KF-642, KF-643, X-22-6191, X-22-4515, KF-6004, KP-341, KF-6001, KF-6002, KP-101, KP-103, KP-104, KP-105, KP-106, KP-109, KP-109, KP-112, KP-120, KP-121, KP-124, KP-125, KP-301, KP-306, KP-310, KP-322, KP-323, KP-327, KP-341, KP-368, KP-369, KP-611, KP-620, KP-621, KP-626, and KP-652 (all of which are manufactured by Shin-Etsu Silicone Co., Ltd.); F-4440, TSF-4300, TSF-4445, TSF-4460, and TSF-4452 (all of which are manufactured by Momentive Performance Materials Co., Ltd.); and BYK300, BYK306, BYK307, BYK310, BYK320, BYK323, BYK330, BYK313, BYK315N, BYK331, BYK333, BYK345, BYK347, BYK348, BYK349, BYK370, BYK377, BYK378, and BYK323 (all of which are manufactured by BYK Chemie).

Examples of the surfactant also include surfactants described in paragraphs 0120 to 0125 of WO2018/179640A, paragraph 0017 of JP4502784B, and paragraphs 0060 to 0071 of JP2009-237362A.

The surfactant may be used alone or in combination of two or more kinds thereof.

In a case where the photosensitive composition contains a surfactant, a content of the surfactant is preferably 0.0001% to 10% by mass, more preferably 0.001% to 5% by mass, and still more preferably 0.005% to 3% by mass with respect to the total solid content of the photosensitive composition.

### [Polymerizable Compound Having No Carboxy Group and Having Ethylenically Unsaturated Group]

The photosensitive composition may contain a polymerizable compound having no carboxy group and having an ethylenically unsaturated group (hereinafter, also simply referred to as “polymerizable compound”).

The polymerizable compound is a polymerizable compound having no carboxy group and having one or more (for example, 1 to 15) ethylenically unsaturated groups in one molecule, and is a compound different from the above-described various components.

The photosensitive composition contains no polymerizable compound having a molecular weight of 2,000 or less, having an ethylenically unsaturated group, and not having a carboxy group, or in a case of containing the polymerizable compound, a content of the polymerizable compound is preferably 5% by mass or less, more preferably less than 3% by mass, still more preferably 1% by mass or less, particularly preferably 0.5% by mass or less, and most preferably 0.1% by mass or less with respect to the total solid content of the photosensitive composition.

Examples of the ethylenically unsaturated group include a (meth)acryloyl group, a vinyl group, and a styryl group.

Examples of the polymerizable compound include a polymerizable compound having one ethylenically unsaturated group in one molecule (hereinafter, also referred to as “monofunctional polymerizable compound”); a polymerizable compound having two ethylenically unsaturated groups in one molecule (hereinafter, also referred to as “bifunctional polymerizable compound”); and a polymerizable compound having three or more ethylenically unsaturated groups in one molecule (hereinafter, also referred to as “tri- or higher functional polymerizable compound”).

Examples of the bifunctional polymerizable compound include tricyclodecane dimethanol di(meth)acrylate, 1,9-nonanediol di(meth)acrylate, and 1,6-hexanediol di(meth)acrylate; and specific examples thereof include tricyclodecane dimethanol diacrylate (A-DCP manufactured by Shin-Nakamura Chemical Co., Ltd.), tricyclodecane dimethanol dimethacrylate (DCP manufactured by Shin-Nakamura Chemical Co., Ltd.), 1,9-nonanediol diacrylate (A-NOD-N manufactured by Shin-Nakamura Chemical Co., Ltd.), and 1,6-hexanediol diacrylate (A-HD-N manufactured by Shin-Nakamura Chemical Co., Ltd.).

Examples of the tri- or higher functional polymerizable compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

The “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the polymerizable compound include a caprolactone-modified compound of a (meth)acrylate compound (KAYARAD (registered trademark) DPCA-20 and the like manufactured by Nippon Kayaku Co., Ltd.; and A-9300-1CL and the like manufactured by Shin-Nakamura Chemical Co., Ltd.), an alkylene oxide-modified compound of a (meth)acrylate compound (KAYARAD RP-1040 and the like manufactured by Nippon Kayaku Co., Ltd.; ATM-35E, A-9300, and the like manufactured by Shin-Nakamura Chemical Co., Ltd.; and EBECRYL (registered trademark) 135 manufactured by Daicel-Allnex Ltd.), and ethoxylated glycerin triacrylate (A-GLY-9E and the like manufactured by Shin-Nakamura Chemical Co., Ltd.).

Examples of the polymerizable compound also include urethane (meth)acrylate (preferably, tri- or higher functional urethane (meth)acrylate). The lower limit of the number of functional groups is preferably 6 or more and more preferably 8 or more. The upper limit of the number of functional groups is preferably 20 or less.

Examples of the tri- or higher functional urethane (meth)acrylate include 8UX-015A (manufactured by Taisei Fine Chemical Co., Ltd.); UA-32P, U-15HA, and UA-1100H (all manufactured by Shin-Nakamura Chemical Co., Ltd.); AH-600 (manufactured by KYOEISHA CHEMICAL Co., LTD.); and UA-306H, UA-306T, UA-306I, UA-510H, and UX-5000 (all manufactured by Nippon Kayaku Co., Ltd.).

The polymerizable compound may be used alone or in combination of two or more kinds thereof.

In a case where the photosensitive composition contains a polymerizable compound, a content of the polymerizable compound may be 6% to 70% by mass with respect to the total solid content of the photosensitive composition.

### [Photopolymerization Initiator]

The photosensitive composition may contain a photopolymerization initiator.

The photopolymerization initiator is a compound different from the above-described various components.

Examples of the photopolymerization initiator include a photoradical polymerization initiator, a photocationic polymerization initiator, and a photoanionic polymerization initiator, and a photoradical polymerization initiator is preferable.

It is preferable that the photosensitive composition does not substantially contain the photopolymerization initiator.

The fact that the photopolymerization initiator is not substantially contained is as described above.

Examples of the photopolymerization initiator include an oxime ester compound (photopolymerization initiator having an oxime ester structure), an aminoacetophenone compound (photopolymerization initiator having an aminoacetophenone structure), a hydroxyacetophenone compound, an acylphosphine oxide compound, and a bistriphenylimidazole compound.

The photopolymerization initiator preferably includes at least one selected from the group consisting of an oxime ester compound and an aminoacetophenone compound, and more preferably includes an oxime ester compound and an aminoacetophenone compound.

Examples of the oxime ester compound include 1,2-octanedione, 1-[4-(phenylthio)phenyl-,2-(O-benzoyloxime)] (product name: IRGACURE OXE-01; IRGACURE series, manufactured by BASF SE), etanone,1-[9-ethyl-6-(2-methylbenzoyl)-9H-carbazol-3-yl]-,1-(O-acetyloxime) (product name: IRGACURE OXE-02, manufactured by BASF SE), [8-[5-(2,4,6-trimethylphenyl)-11-(2-ethylhexyl)-11H-benzo[a]carbazoyl][2-(2,2,3,3-tetrafluoropropoxy)phenyl]methanone-(O-acetyloxime) (product name: IRGACURE OXE-03, manufactured by BASF SE), 1-[4-[4-(2-benzofuranylcarbonyl)phenyl]thio]phenyl]-4-methylpentanone-1-(O-acetyloxime) (product name: IRGACURE OXE-04, manufactured by BASF SE, and product name: Lunar 6, manufactured by DKSH Management Ltd.), 1-[4-(phenylthio)phenyl]-3-cyclopentylpropan-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(0-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by Changzhou Tronly New Electronic Materials Co., Ltd.).

Examples of the aminoacetophenone compound include 2-(dimethylamino)-2-[(4-methylphenyl)methyl]-1-[4-(4-morpholinyl)phenyl]-1-butanone (product name: Omnirad 379EG; Omnirad series are manufactured by IGM Resins B.V.), 2-methyl-1-(4-methylthiophenyl)-2-morpholinopropan-1-one (product name: Omnirad 907), and APi-307 (1-(biphenyl-4-yl)-2-methyl-2-morpholinopropan-1-one, manufactured by Shenzhen UV-ChemTech Co., Ltd.).

Examples of the photopolymerization initiator also include 2-hydroxy-1-{4-[4-(2-hydroxy-2-methyl-propionyl)-benzyl]phenyl}-2-methyl-propan-1-one (product name: Omnirad 127), 2-benzyl-2-dimethylamino-1-(4-morpholinophenyl)-butanone-1 (product name: Omnirad 369), 2-hydroxy-2-methyl-1-phenyl-propan-1-one (product name: Omnirad 1173), 1-hydroxy-cyclohexyl-phenyl-ketone (product name: Omnirad 184), 2,2-dimethoxy-1,2-diphenylethane-1-one (product name: Omnirad 651), 2,4,6-trimethylbenzoyl-diphenylphosphine oxide (product name: Omnirad TPO H), and bis(2,4,6-trimethylbenzoyl) phenylphosphine oxide (product name: Omnirad 819).

Examples the photopolymerization initiator also include photopolymerization initiators described in paragraphs 0031 to 0042 of JP2011-095716A and paragraphs 0064 to 0081 of JP2015-014783A.

The photopolymerization initiator may be used alone or in combination of two or more kinds thereof.

In a case where the photosensitive composition contains a photopolymerization initiator, a content of the photopolymerization initiator is preferably 0.1% to 15% by mass, more preferably 0.5% to 10% by mass, and still more preferably 1% to 5% by mass with respect to the total solid content of the photosensitive composition.

### [Other Additives]

The photosensitive composition may contain an additive other than the above-described various components.

Examples of other additives include a solvent, impurities, a plasticizer, a sensitizer, and an alkoxysilane compound.

Examples of the plasticizer, the sensitizer, and the alkoxysilane compound include those described in paragraphs 0097 to 0119 of WO2018/179640A.

As the solvent, a known solvent can be used as long as it can dissolve or disperse the various components other than the solvent.

Specific examples thereof include water, an alkylene glycol ether solvent, an alkylene glycol ether acetate solvent, an alcohol solvent (for example, methanol, ethanol, and the like), a ketone solvent (for example, acetone, methyl ethyl ketone, and the like), an aromatic hydrocarbon solvent (for example, toluene and the like), an aprotic polar solvent (for example, N,N-dimethylformamide and the like), a cyclic ether solvent (for example, tetrahydrofuran and the like), an ester solvent (for example, n-propyl acetate and the like), an amide solvent, a lactone solvent, and a mixed solvent including two or more of these solvents.

The solvent may be used alone or in combination of two or more kinds thereof.

In a case where the photosensitive composition contains a solvent, a content of the solvent is preferably 50 to 1,900 parts by mass, more preferably 100 to 1,200 parts by mass, and still more preferably 100 to 900 parts by mass with respect to 100 parts by mass of the total solid content of the composition.

The photosensitive composition may contain impurities.

Examples of the impurities include sodium, potassium, magnesium, calcium, iron, manganese, copper, aluminum, titanium, chromium, cobalt, nickel, zinc, tin, halogen, and ions of these. Halide ion, sodium ion, and potassium ion are easily mixed as the impurities, so that the following content is preferable.

A content of the impurities is preferably 80 ppm by mass or less, more preferably 10 ppm by mass or less, and still more preferably 2 ppm by mass or less with respect to the total solid content of the photosensitive composition. The lower limit thereof is usually 0 ppb by mass or more with respect to the total solid content of the photosensitive composition, and it may be 1 ppb by mass or more or 0.1 ppm by mass or more.

Examples of a method for adjusting the content of the impurities include using raw materials having a low content of impurities as raw materials of the various components of the photosensitive composition; purifying the various components; and preventing the impurities from being mixed in the photosensitive composition during the preparation of the photosensitive composition.

The impurities can be quantified by a known method such as inductively coupled plasma (ICP) emission spectroscopy, atomic absorption spectroscopy, and ion chromatography.

In the photosensitive composition, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low. Specifically, the content of these compounds is preferably 100 ppm by mass or less, more preferably 20 ppm by mass or less, and still more preferably 4 ppm by mass or less with respect to the total solid content of the photosensitive composition. The lower limit of the above-described content maybe 10 ppb by mass or more or 100 ppb by mass or more with respect to the total solid content of the photosensitive composition.

The content of these compounds can be adjusted by the same method as that for the above-described impurities. In addition, these compounds can be quantified by a known measuring method.

It is preferable that the photosensitive composition can be used for forming a photosensitive layer which can be patterned by exposure and development with an aqueous solution of 1% by mass sodium carbonate at a liquid temperature of 25° C.

Examples of a pattern forming method such as exposure conditions include a pattern forming method described later.

### [Transfer Film]

The transfer film includes a temporary support and a photosensitive layer formed of the above-described photosensitive composition.

In the transfer film, the amount of the carboxy group included in the compound A in the photosensitive layer is reduced by exposure.

the FIGURE is a schematic cross-sectional view showing an example of an embodiment of the transfer film.

A transfer film 10 shown in the FIGURE has a configuration in which a temporary support 12, a photosensitive layer 14, and a cover film 16 are laminated in this order.

The transfer film 10 shown in the FIGURE is in a form in which the cover film 16 is disposed, but the cover film 16 may not be disposed. In addition, as will be described later, an interlayer and/or a thermoplastic resin layer may be further included.

Hereinafter, each member included in the transfer film will be described in detail.

### [Temporary Support]

The temporary support is a support which supports the photosensitive layer and can be peeled off from the photosensitive layer.

From the viewpoint that the photosensitive layer can be exposed through the temporary support in a case where the photosensitive layer is exposed in a patterned manner, the temporary support preferably has light-transmitting property.

The pattern exposure refers to exposure in a patterned manner, in which an exposed portion and a non-exposed portion are present.

In addition, the “having light-transmitting property” means that a transmittance of light having a main wavelength used for exposure (may be pattern exposure or entire exposure) is 50% or more. From the viewpoint of more excellent exposure sensitivity, the transmittance of the light having the main wavelength used for exposure is preferably 60% or more, and more preferably 70% or more. The transmittance can be measured using MCPD Series manufactured by Otsuka Electronics Co., Ltd.

Examples of the temporary support include a glass substrate, a resin film, and paper, and from the viewpoint of more excellent strength and flexibility, a resin film is preferable. Examples of the resin film include a polyethylene terephthalate film, a cellulose triacetate film, a polystyrene film, and a polycarbonate film; and a biaxial stretching polyethylene terephthalate film is preferable.

From the viewpoint of pattern formability during the pattern exposure through the temporary support and transparency of the temporary support, it is preferable that the number of particles, foreign substances, and defects included in the temporary support is small. Specifically, the number of fine particles, foreign substances, and defects having a diameter of 2 μm or more is preferably 50 pieces/10 mm² or less, more preferably 10 pieces/10 mm² or less, and still more preferably 3 pieces/10 mm² or less. The lower limit thereof may be 1 piece/10 mm² or more.

From the viewpoint of further improving handleability, the temporary support preferably has a layer in which 1 piece/mm² or more particles with a diameter of 0.5 to 5 μm are present on a surface opposite to the side where the photosensitive layer is formed, and it is more preferable that 1 to 50 pieces/mm² are present.

From the viewpoint of ease of handling and excellent general-purpose properties, a thickness of the temporary support is preferably 5 to 200 μm and more preferably 10 to 150 μm. From the viewpoint of strength as a support, flexibility required for bonding to a substrate for forming a circuit wiring, and light-transmitting property required in a first exposing step, the thickness of the temporary support can be appropriately selected according to a material.

Examples of the temporary support include those described in paragraphs 0017 and 0018 of JP2014-085643A, paragraphs 0019 to 0026 of JP2016-027363A, paragraphs 0041 to 0057 of WO2012/081680A, and paragraphs 0029 to 0040 of WO2018/179370A, the contents of which are incorporated in the present specification.

Examples of the temporary support include COSMOSHINE (registered trademark) A4100 (manufactured by TOYOBO Co., Ltd.), COSMOSHINE (registered trademark) A4300 (manufactured by TOYOBO Co., Ltd.), COSMOSHINE (registered trademark) A4160 (manufactured by TOYOBO Co., Ltd.), COSMOSHINE (registered trademark) A4360 (manufactured by TOYOBO Co., Ltd.), LUMIRROR (registered trademark) 16FB40 (manufactured by Toray Industries, Inc.), and LUMIRROR (registered trademark) 16QS62 (manufactured by Toray Industries, Inc.); and a biaxially stretched polyethylene terephthalate film having a thickness of 16 μm, a biaxially stretched polyethylene terephthalate film having a thickness of 12 μm, or a biaxially stretched polyethylene terephthalate film having a thickness of 9 μm is preferable.

The temporary support may be a recycled product. Examples of the recycled product include films obtained by washing used films and the like, making the used films and the like into chips, and using the chips as a material. Examples of the recycled product include Ecouse (registered trademark) series manufactured by Toray Industries, Inc.

### [Photosensitive Layer]

The photosensitive layer is a layer formed of the above-described photosensitive composition.

The photosensitive layer contains the compound A, and has a mechanism in which the content of the carboxy group in the compound A is reduced by exposure.

A reduction rate of the content of the carboxy group in the compound A in the photosensitive layer can be calculated from a reduction rate of a height of peak top of a maximal absorption peak present in a wavelength range of 1680 to 1720 cm⁻¹, by measuring an infrared (IR) spectrum of the photosensitive layer before and after exposure. In general, a maximal absorption peak of C═O stretching and contracting of the carboxy group is usually present in the wavelength range of 1680 to 1720 cm⁻¹.

The various components which can be contained in the photosensitive layer are synonymous with the various components which can be contained in the photosensitive composition described above, and suitable aspects thereof are also the same.

However, suitable numerical ranges of the contents of the various components in the photosensitive layer are the same as suitable ranges in which “content (% by mass) of various components with respect to the total solid content of the photosensitive composition” described above is read as “content (% by mass) of various components with respect to the total mass of the photosensitive layer”. Specifically, the description that “the content of the polymer A is usually 1% by mass or more, preferably 15% by mass or more with respect to the total solid content of the photosensitive composition” is read as “the content of the polymer A is usually 1% by mass or more, preferably 15% by mass or more with respect to the total mass of the photosensitive layer”.

### <Thickness of Photosensitive Layer>

An average thickness of the photosensitive layer is preferably 0.5 to 40 μm and more preferably 0.5 to 25 μm. In a case where the average thickness of the photosensitive layer is m or less, resolution of the pattern is more excellent, and in a case where the average thickness of the photosensitive layer is 0.5 μm or more, it is preferable from the viewpoint of reliability. The average thickness of the photosensitive layer is more preferably 3 to 20 μm.

### [Interlayer and Thermoplastic Resin Layer]

The transfer film may include an interlayer and/or a thermoplastic resin layer.

Examples of the interlayer and the thermoplastic resin layer include those described in paragraphs 0164 to 0204 of WO2021/166719A, the contents of which are incorporated in the present specification.

### [Cover Film]

The transfer film may include a cover film.

The cover film preferably has 5 pieces/m² or less of the number of fisheyes with a diameter of 80 μm or more in the cover film. The “fisheye” means that, in a case where a material is hot-melted, kneaded, extruded, biaxially stretched, cast and/or the like to produce a film, foreign substances, undissolved substances, oxidatively deteriorated substances, and/or the like of the material are incorporated into the film.

The number of particles having a diameter of 3 μm or more, included in the cover film, is preferably 30 particles/mm² or less, more preferably 10 particles/mm² or less, and still more preferably 5 particles/mm² or less. As a result, it is possible to suppress defects caused by ruggedness due to the particles included in the cover film being transferred to the photosensitive layer.

An arithmetic average roughness Ra of a surface of the cover film is preferably 0.01 m or more, more preferably 0.02 μm or more, and still more preferably 0.03 μm or more. In a case where Ra is within such a range, for example, in a case where the transfer film has a long shape, take-up property in a case of winding the transfer film can be improved. In addition, from the viewpoint of suppressing defects during transfer, Ra is preferably less than 0.50 μm, more preferably 0.40 μm or less, and still more preferably 0.30 μm or less.

Examples of the cover film include a polyethylene terephthalate film, a polypropylene film, a polystyrene film, and a polycarbonate film.

Examples of the cover film include films described in paragraphs 0083 to 0087 and 0093 of JP2006-259138A.

Examples of the cover film include ALPHAN (registered trademark) FG-201 (manufactured by Oji F-Tex Co., Ltd.), ALPHAN (registered trademark) E-201F (manufactured by Oji F-Tex Co., Ltd.), Cerapeel (registered trademark) 25WZ (manufactured by TORAY ADVANCED FILM CO., LTD.), and LUMIRROR (registered trademark) 16QS62 (16KS40) (manufactured by Toray Industries, Inc.).

The cover film may be a recycled product. Examples of the recycled product include films obtained by washing used films and the like, making the used films and the like into chips, and using the chips as a material. Examples of the recycled product include Ecouse (registered trademark) series manufactured by Toray Industries, Inc.

### [Other Layers]

The transfer film may include a layer other than the above-described layers.

Examples of other layers include a layer of high refractive index.

Examples of the layer of high refractive index include those described in paragraphs 0168 to 0188 of WO2021/187549A, the contents of which are incorporated in the present specification.

### [Manufacturing Method of Transfer Film]

As a manufacturing method of the transfer film, a known manufacturing method can be adopted.

As the manufacturing method of the transfer film, it is preferable that the photosensitive layer is formed on a temporary support by a coating method.

Examples of the manufacturing method of the transfer film 10 shown in the FIGURE include a method including a step of applying a photosensitive composition onto a surface of the temporary support to form a coating film, and then drying the coating film to form the photosensitive layer.

The transfer film 10 shown in the FIGURE is manufactured by compression-bonding a cover film to the photosensitive layer of the transfer film manufactured by the above-described manufacturing method. In addition, the transfer film 10 shown in the FIGURE may be wound after the manufacturing to be stored as a transfer film in a roll form. The roll-shaped transfer film is provided as it is in a bonding step described later with the substrate in a roll-to-roll method.

In addition, the transfer film may include an interlayer and/or a thermoplastic resin layer between the temporary support and the photosensitive layer.

Examples of a composition for forming the interlayer, a method for forming the interlayer, a composition for forming the thermoplastic resin layer, and a method for forming the thermoplastic resin layer include paragraphs 0133 to 0136 and paragraphs 0143 and 0144 of WO2021/033451A, the contents of which are incorporated in the present specification.

### <Method for Forming Photosensitive Layer>

As a method of forming the photosensitive layer, a known method can be used, and examples thereof include a method of forming the photosensitive layer by applying and drying a photosensitive composition.

As described above, the photosensitive composition contains the compound A, the compound β, and the filler.

Examples of an applying method include slit coating, spin coating, curtain coating, and inkjet coating.

It is preferable that the photosensitive composition further contains a solvent. The solvent has the same meaning as the solvent which can be contained in the above-described photosensitive composition, and a suitable aspect thereof is also the same.

### <Example of Manufacturing Method of Transfer Film>

In a case of forming the photosensitive layer in the transfer film, the photosensitive composition may be any of an aqueous composition or an organic solvent-based composition.

In a manufacturing method of the transfer film including the interlayer between the thermoplastic resin layer and the photosensitive layer, from the viewpoint of more excellent resolution due to suppression of interlayer mixing with the interlayer, the photosensitive composition is preferably an organic solvent-based composition. On the other hand, in the manufacturing method of the transfer film not having the interlayer between the thermoplastic resin layer and the photosensitive layer, from the viewpoint of further improving the resolution due to the suppression of interlayer mixing with the thermoplastic resin layer, the photosensitive composition is preferably an aqueous composition.

The aqueous composition means that the solvent includes water.

As the solvent in the aqueous composition, water alone or a mixed solvent of water and a lower alcohol having 1 to 3 carbon atoms is preferable, and from the viewpoint of more excellent drying properties, a mixed solvent of water and a lower alcohol having 1 to 3 carbon atoms is more preferable, and a mixed solvent of methanol and water is still more preferable.

In the aqueous composition, a content of the water is preferably 30% by mass or more and more preferably 40% by mass or more with respect to the total mass of the solvent. The upper limit thereof may be 100% by mass or less.

In a case where the photosensitive composition is an aqueous composition, from the viewpoint of more excellent solubility in a solvent, it is preferable that the compound A in the photosensitive composition is in an ammonium salt form.

With regard to the ammonia salt of the compound A, in a case where the photosensitive composition is applied onto the thermoplastic resin layer and dried for formation, in drying, ammonia having a boiling point lower than that of water is likely to be volatilized, so that the carboxy group is regenerated. That is, in the photosensitive layer in the transfer film, the ammonium salt of the compound A can be contained as the compound A even in a case where the ammonium salt of the compound A is used as the initiator.

In a case where the photosensitive composition contains an ammonium salt of the compound A, examples of drying conditions in a drying treatment of the coating film of the photosensitive composition include a method of heating the coating film to 40° C. to 150° C.

In addition, in a case where the photosensitive composition is an aqueous composition, from the viewpoint of more excellent stability of the ammonium salt structure, a pH of the photosensitive composition is preferably 7.0 to 10.0 and more preferably 7.0 to 8.5.

### [Applications]

The above-described photosensitive composition, the above-described transfer film, and the pattern (cured film) obtained using the above-described photosensitive composition or the photosensitive layer of the above-described transfer film can be applied to various applications. For example, these can be applied to an electrode protective film, an insulating film, a flattening film, an overcoat film, a hard coat film, a passivation film, a partition wall, a spacer, a microlens, an optical filter, an antireflection film, an etching resist, or a plating member. More specific examples thereof include a protective film or an insulating film for a touch panel electrode, a protective film or an insulating film for a printed wiring board, a protective film or an insulating film for a TFT substrate, an interlayer insulating film in a build-up substrate of a semiconductor package, a color filter, an overcoat film for a color filter, and an etching resist for a wiring line formation.

### [Pattern Forming Method]

The transfer film may be used in a pattern forming method.

As the pattern forming method, a pattern forming method using the above-described transfer film may be used.

Specifically, it is preferable to include a step of forming a photosensitive layer on a base material using the above-described photosensitive composition or the above-described transfer film, a step of exposing the photosensitive layer in a patterned manner, and a step of developing the exposed photosensitive layer (for example, alkali development, organic solvent development, or the like) in this order.

Examples of the step of forming the photosensitive layer using the photosensitive composition include the method of forming the photosensitive layer in the above-described manufacturing method of the transfer film. Examples of the step of exposing the photosensitive layer in a patterned manner and the step of developing the exposed photosensitive layer (for example, alkali development, organic solvent development, or the like) include each step in a pattern forming method described later.

In a case where the above-described development is an organic solvent development, it is preferable to include a step of further exposing the obtained pattern.

Examples of embodiments of the pattern forming method according to the present invention include pattern forming methods of an embodiment 1 and an embodiment 2. Hereinafter, each step of the pattern forming method will be described in detail.

### Embodiment 1 of Pattern Forming Method

An embodiment 1 of the pattern forming method includes steps X1 to X3.

The step X2 corresponds to a step of reducing the content of the carboxy group derived from the compound A included in the photosensitive layer by the exposure. However, in a case where the developer in the above-described step X3 is an organic solvent developer, it is preferable that a step X4 is further provided after the step X3.

Step X1: step of bringing a surface of the photosensitive layer in the transfer film on an opposite side of a temporary support side into contact with a base material to bond the transfer film and the base material

Step X2: step of exposing the photosensitive layer in a patterned manner

Step X3: step of developing the photosensitive layer with a developer (for example, an alkali developer, an organic solvent developer, or the like)

Step X4: step of further exposing the pattern formed by the development after the developing step of the step X3

In a case where an alkali developer is used as the developer in the step X3, it is preferable that the above-described photosensitive layer is a photosensitive layer formed of the photosensitive composition of the embodiment X-1-a1 and the photosensitive composition of the embodiment X-1-a2. In a case where the organic solvent developer is used as the developer in the step X3, the above-described photosensitive layer is preferably the photosensitive layer of the embodiment X-1-a1.

The embodiment 1 of the pattern forming method is preferably adopted to a transfer film including the photosensitive layer formed from the photosensitive composition of the embodiment X-1-a1 and the photosensitive composition of the embodiment X-1-a2 described above.

In addition, it is preferable that the embodiment 1 of the pattern forming method includes a step of peeling off the temporary support between the step X1 and the step X2 or between the step X2 and the step X3.

### <Step X1>

The embodiment 1 of the pattern forming method includes a step of bringing a surface of the photosensitive layer in the transfer film on an opposite side of a temporary support side into contact with a base material to bond the transfer film and the base material.

### (Base Material)

Examples of the base material include a glass base material, a glass epoxy base material, a silicon base material, a resin base material, and a base material having a conductive layer. Examples of the base material included in the base material having a conductive layer include the above-described base materials.

The above-described base material is preferably transparent.

A refractive index of the above-described base material is preferably 1.50 to 1.52.

The above-described base material may be composed of a translucent base material such as a glass substrate, and for example, tempered glass typified by Gorilla glass of Corning Incorporated can also be used. In addition, as the material contained in the above-described base material, materials used in JP2010-086684A, JP2010-152809A, and JP2010-257492A are also preferable.

In a case where the above-described base material includes a resin base material, as the resin base material, a resin film having a small optical distortion and/or a high transparency is more preferable. Specific examples thereof include polyethylene terephthalate (PET), polyethylene naphthalate, polycarbonate, triacetyl cellulose, and a cycloolefin polymer.

As the base material included in the base material having a conductive layer, from the viewpoint of manufacturing by a roll-to-roll method, a resin base material is preferable and a resin film is more preferable.

Examples of the conductive layer include any conductive layer used for general circuit wiring or touch panel wiring.

As the conductive layer, from the viewpoint of conductivity and fine line formability, one or more layers selected from the group consisting of a metal layer (for example, a metal foil or the like), a conductive metal oxide layer, a graphene layer, a carbon nanotube layer, and a conductive polymer layer are preferable, a metal layer is more preferable, and a copper layer or a silver layer is still more preferable.

In addition, the conductive layer in the base material having a conductive layer may be one layer or two or more layers.

In a case where the base material having a conductive layer includes two or more conductive layers, it is preferable that each conductive layer is a conductive layer formed of different materials.

Examples of a material of the conductive layer include simple substances of metal and conductive metal oxides.

Examples of the simple substance of metal include Al, Zn, Cu, Fe, Ni, Cr, Mo, Ag, and Au.

Examples of the conductive metal oxide include indium tin oxide (ITO), indium zinc oxide (IZO), and SiO₂. The “conductive” means that a volume resistivity is less than 1×10⁶ Ω·cm, preferably less than 1×10⁴ Ω·cm.

In a case where the number of conductive layers in the base material having a conductive layer is 2 or more, it is preferable that at least one conductive layer among the conductive layers includes the conductive metal oxide.

### (Procedure of Step X1)

The above-described step X1 is preferably a bonding step of pressurization by a roll or the like and heating. A known laminator such as a laminator, a vacuum laminator, and an auto-cut laminator can be used for the bonding.

The step X1 is preferably carried out by a roll-to-roll method. The base material to which the transfer film is bonded is preferably a resin film or a resin film having a conductive layer.

The roll-to-roll method refers to a method in which, as the base material, a base material which can be wound up and unwound is used, a step (hereinafter, also referred to as an “unwinding step”) of unwinding the base material before any of the steps included in the pattern forming method according to the embodiment of the present invention, a step (hereinafter, also referred to as a “winding step”) of winding the base material is included after any of the steps, and at least one of the steps (preferably, all steps or all steps other than the heating step) is performed while transporting the base material.

As an unwinding method in the unwinding step and a winding method in the winding step, a known method may be used in the manufacturing method to which the roll-to-roll method is adopted.

### <Step X2>

The embodiment 1 of the pattern forming method includes a step (step X2) of exposing the photosensitive layer in a patterned manner after the above-described step X1. The step X2 corresponds to a step of reducing the content of the carboxy group included in the compound A in the photosensitive layer by the exposure. More specifically, it is preferable that, by using light having a wavelength which excites the specific structure of the compound β (preferably, the compound B) and/or the specific structure of the compound A in the photosensitive layer, the photosensitive layer is exposed in a patterned manner.

Detailed arrangement and specific size of the pattern in the exposing step are not particularly limited.

For example, in a case where the embodiment 1 of the pattern forming method is adopted to the manufacturing of a circuit wiring, from the viewpoint of improving display quality of a display device (for example, a touch panel) including an input device having the circuit wiring manufactured by the embodiment 1 of the pattern forming method, and viewpoint of reducing an area occupied by a lead-out wiring as much as possible, at least a part of the pattern (in particular, a portion corresponding to a portion of the electrode pattern of the touch panel and the lead-out wiring) is preferably a thin line having a width of 100 μm or less, and more preferably a thin line having a width of 70 μm or less.

As a light source used for the exposure, any light source which emits light in a wavelength range capable of reducing the content of the carboxy group in the compound A in the photosensitive layer (light having a wavelength which excites the specific structure of the compound β (preferably, the compound B) and/or the specific structure of the compound A in the photosensitive layer; examples thereof include light in a wavelength range of 254 nm, 313 nm, 365 nm, 405 nm, and the like) can be appropriately selected. Specific examples thereof include an ultra-high pressure mercury lamp, a high pressure mercury lamp, a metal halide lamp, and a light emitting diode (LED).

An exposure amount is preferably 10 to 10,000 mJ/cm² and more preferably 50 to 3,000 mJ/cm².

In the step X2, the temporary support may be peeled off from the photosensitive layer and then the pattern exposure may be performed, or before peeling off the temporary support, the pattern exposure may be performed through the temporary support and then the temporary support may be peeled off. In order to prevent mask contamination due to contact between the photosensitive layer and the mask and to avoid an influence of foreign substance adhering to the mask on the exposure, it is preferable to perform the pattern exposure without peeling off the temporary support. The pattern exposure may be an exposure through a mask or a direct exposure using a laser or the like.

Before the step X3 described later, the temporary support is peeled off from the photosensitive layer.

### <Step X3>

The embodiment 1 of the pattern forming method includes a step (step X3) of, after the above-described step X2, developing the photosensitive layer exposed in a patterned manner with a developer (for example, alkali developer, organic solvent developer, or the like).

By reducing the content of the carboxy group in the photosensitive layer of the exposed portion, a difference in solubility (dissolution contrast) in the developer may occur between the exposed portion and the non-exposed portion of the photosensitive layer which has undergone the step X2. By forming the dissolution contrast in the photosensitive layer, it is possible to form a pattern in the step X3. In a case where the developer in the above-described step X3 is an alkali developer, the non-exposed portion is removed and a negative pattern is formed by performing the above-described step X3. On the other hand, in a case where the developer in the above-described step X3 is an organic solvent developer, the exposed portion is removed and a positive pattern is formed by performing the above-described step X3. For the obtained positive pattern, it is necessary to perform a treatment for reducing the content of the carboxy group included in the compound A by the step X4 described later.

### (Alkali Developer)

The alkali developer is not particularly limited as long as the non-exposed portion of the photosensitive resin layer can be removed, and a known developer such as a developer described in JP1993-072724A (JP-H5-072724A) can be used.

As the alkali developer, an alkali aqueous solution-based developer containing a compound having a pKa of 7 to 13 at a concentration of 0.05 to 5 mol/L is preferable. In addition, the alkali developer may further contain a water-soluble organic solvent, a surfactant, and the like. As the alkali developer, developers described in paragraph 0194 of WO2015/093271A are preferable.

A concentration of water in the alkali developer is preferably 50% by mass or more, more preferably 60% by mass or more, still more preferably 85% by mass or more, particularly preferably 90% by mass or more, and most preferably 95% by mass or more. The upper limit thereof may be less than 100% by mass.

Examples of the alkali developer include a sodium carbonate aqueous solution, a potassium carbonate aqueous solution, a sodium hydroxide aqueous solution, a potassium hydroxide aqueous solution, and a tetramethylammonium hydroxide aqueous solution. Examples of a concentration of the above-described alkali developer (alkali component constituting the alkali developer) include a 0.1% by mass aqueous solution, a 1.0% by mass aqueous solution, and a 2.38% by mass aqueous solution.

### (Organic Solvent Developer)

The organic solvent developer is not particularly limited as long as it can remove the exposed portion of the photosensitive resin layer, and for example, a developer including an organic solvent such as a ketone-based solvent, an ester-based solvent, an alcohol-based solvent, an amide-based solvent, an ether-based solvent, and a hydrocarbon-based solvent can be used.

Examples of the organic solvent developer include cyclopentanone and propylene glycol monomethyl ether acetate.

In the organic solvent developer, a plurality of organic solvents may be mixed, or may be mixed with an organic solvent other than the above or water and used. However, in order to fully exert the effect of the present invention, a moisture content of the organic solvent developer as a whole is preferably less than 10% by mass, and the organic solvent developer is more preferably substantially free of water. A concentration of the organic solvent (in a case of mixing a plurality of organic solvents, a total thereof) in the organic solvent developer is preferably 50% by mass or more, more preferably 60% by mass or more, still more preferably 85% by mass or more, particularly preferably 90% by mass or more, and most preferably 95% by mass or more. The upper limit thereof may be 100% by mass or less.

Examples of the developing method include puddle development, shower development, spin development, and dip development. In the shower development, unnecessary portions can be removed by spraying the developer on the photosensitive resin layer after the exposure with a shower. In addition, after the development, it is also preferable to spray a washing agent and the like with a shower and rub with a brush and the like to remove the developing residue. A liquid temperature of the developer is preferably 20° C. to 40° C.

The embodiment 1 of the pattern forming method may or may not further include a post-baking step of heat-treating a pattern including the photosensitive layer obtained by development.

The post-baking is preferably performed in an environment of 8.1 to 121.6 kPa, and more preferably performed in an environment of 50.66 kPa or more. On the other hand, it is more preferably performed in an environment of 111.46 kPa or less, and still more preferably performed in an environment of 101.3 kPa or less.

The temperature of the post-baking is preferably 80° C. to 250° C., more preferably 110° C. to 170° C., and still more preferably 130° C. to 150° C.

The time of the post-baking is preferably 1 to 60 minutes, more preferably 2 to 50 minutes, and still more preferably 5 to 40 minutes.

The post-baking may be performed in an air environment or a nitrogen replacement environment.

### <Step X4>

In a case where the developer in the above-described step X3 is an organic solvent developer, the step X4 is performed on the obtained positive pattern. The step X4 corresponds to a step of exposing the positive pattern obtained in the step X3 to reduce the content of the carboxy group derived from the compound A. More specifically, it is preferable that, by using light having a wavelength which excites the specific structure of the compound B and/or the specific structure of the compound A in the photosensitive layer, the photosensitive layer is exposed in a patterned manner.

A light source and exposure amount used for the exposure are the same as the light source and exposure amount described in the step X1, and suitable aspects thereof are also the same.

### Embodiment 2 of Pattern Forming Method

An embodiment 2 of the pattern forming method includes a step Y1, a step Y2P, and a step Y3 in this order, and further includes a step Y2Q (step of further exposing the photosensitive layer exposed in the step Y2P) between the step Y2P and the step Y3 or after the step Y3.

Step Y1: step of bringing a surface of the photosensitive layer in the transfer film on an opposite side of a temporary support side into contact with a base material to bond the transfer film and the base material

Step Y2P: step of exposing the photosensitive layer

Step Y3: step of developing the photosensitive layer with a developer

The embodiment 2 of the pattern forming method corresponds to an applicable aspect in which the photosensitive layer further includes a photopolymerization initiator and a polymerizable compound. Therefore, the pattern forming method of the embodiment 2 is preferably adopted to a transfer film including the photosensitive layer formed from the photosensitive composition of the embodiment X-1-a3 described above.

Hereinafter, the embodiment 2 of the pattern forming method will be described, but the step Y1 and the step Y3 are the same as the step X1 and the step X3, respectively, so that the description thereof will be omitted.

It is sufficient that the step Y3 is performed at least after the step Y2P, and the step Y3 may be performed between the step Y2P and the step Y2Q.

The embodiment 2 of the pattern forming method may or may not further include, after the step Y3, a post-baking step of heat-treating a pattern including the photosensitive layer obtained by development. The post-baking step can be performed by the same method as the post-baking step which may be included in the above-described embodiment 1 of the pattern forming method. In a case where the step Y3 is performed between the step Y2P and the step Y2Q, the post-baking step may be performed before the step Y2Q or after the step Y2Q as long as it is performed after the step Y3.

In addition, it is preferable that the embodiment 2 of the pattern forming method includes a step of peeling off the temporary support between the step Y1 and the step Y2P or between the step Y2P and the step Y3.

<Step Y2P and step Y2Q>

The embodiment 2 of the pattern forming method includes a step (step Y2P) of exposing the photosensitive layer through the step Y1 and a step (step Y2Q) of further exposing the exposed photosensitive layer.

One of the exposure treatments (the step Y2P and the step Y2Q) is an exposure for mainly reducing the content of the carboxy group included in the compound A by the exposure, and the other of the exposure treatments (the step Y2P and the step Y2Q) is an exposure for mainly causing a polymerization reaction of the polymerizable compound based on the photopolymerization initiator. In addition, the exposure treatments (the step Y2P and the step Y2Q) may be either the entire exposure or the pattern exposure, but any one of the exposure treatments is the pattern exposure.

For example, in a case where the step Y2P is a pattern exposure for reducing the content of the carboxy group included in the compound A by the exposure, the developer used in the step Y3 may be an alkali developer or an organic solvent developer. However, in a case of developing with an organic solvent developer, the step Y2Q is usually performed after the step Y3, and in the developed photosensitive layer (pattern), the polymerization reaction of the polymerizable compound based on the photopolymerization initiator occurs, and the content of the carboxy group included in the compound A is reduced.

In addition, for example, in a case where the step Y2P is a pattern exposure for causing a polymerization reaction of the polymerizable compound based on the photopolymerization initiator, the developer used in the step Y3 is usually an alkali developer. In this case, the step Y2Q may be performed before or after the step Y3, and the step Y2Q in a case of being performed before the step Y3 is usually a pattern exposure.

In the step Y2P and the step Y2Q, examples of the light source used for the exposure include the light source in the step X2 described above.

In the exposure for reducing the content of the carboxy group included in the compound A in the photosensitive layer, an exposure amount is preferably 10 to 10,000 mJ/cm² and more preferably 50 to 3,000 mJ/cm².

In the exposure for causing a reaction of the polymerizable compound based on the photopolymerization initiator in the photosensitive layer, an exposure amount is preferably 5 to 200 mJ/cm² and more preferably 10 to 150 mJ/cm².

In the step Y2P and the step Y2Q, same as the above-described step X2, the temporary support may be peeled off from the photosensitive layer and then the pattern exposure may be performed, or before peeling off the temporary support, the pattern exposure may be performed through the temporary support and then the temporary support may be peeled off.

Examples of detailed arrangement and specific size of the pattern in the exposing step include the aspects in the step X2.

### [Suitable Aspect]

As the pattern forming method, it is also preferable to include a step Y1, a step Y2A, and a step Y3 in this order. In addition, it is also preferable that the pattern forming method further includes a step Y2B after the step Y3. It is also preferable that one of the step Y2A or the step Y2B is an exposing step for reducing the content of the carboxy group described from the compound A by exposure, and the other one is an exposing step for mainly causing a polymerization reaction of the polymerizable compound based on the photopolymerization initiator.

Step Y1: step of bringing a surface of the photosensitive layer in the transfer film on an opposite side of a temporary support side into contact with a base material to bond the transfer film and the base material

Step Y2A: step of exposing the photosensitive layer in a patterned manner

Step Y3: step of developing the photosensitive layer with an alkali developer to form a patterned photosensitive layer

Step Y2B: step of exposing the patterned photosensitive layer

In addition, it is preferable that the above-described pattern forming method includes a step of peeling off the temporary support between the step Y1 and the step Y2A or between the step Y2A and the step Y3.

The above-described step Y2A is preferably an exposing step for causing a polymerization reaction of the polymerizable compound based on the photopolymerization initiator, and the above-described step Y2B is preferably an exposing step for reducing the content of the carboxy group derived from the compound A by the exposure.

[Optional Step which May be Included in Pattern Forming Method]

The pattern forming method (the pattern forming method of the embodiment 1, the pattern forming method of the embodiment 2, the pattern forming method of the above-described suitable aspect, or the like) may include any steps (for example, other steps) in addition to those described above. Examples thereof include the following steps, but the optional step is not limited to the following steps.

### <Cover Film Peeling Step>

In the above-described pattern forming method, in a case where the transfer film includes a cover film, it is preferable to include a step (hereinafter, also referred to as a “cover film peeling step”) of peeling off the cover film of the transfer film. As a method of peeling off the cover film, and a known method can be adopted.

### <Step of Reducing Visible Light Reflectivity>

In a case where the substrate is the substrate having a conductive layer, the above-described pattern forming method may further include a step of performing a treatment of reducing a visible light reflectivity of the conductive layer. In a case where the above-described substrate is a substrate having a plurality of conductive layers, the treatment of reducing the visible light reflectivity may be performed on some conductive layers or all conductive layers.

Examples of the treatment of reducing the visible light reflectivity include an oxidation treatment. For example, by oxidizing copper to copper oxide, the visible light reflectivity of the conductive layer can be reduced due to blackening.

Examples of a suitable aspect of the treatment of reducing the visible light reflectivity include the descriptions in paragraphs 0017 to 0025 of JP2014-150118A, and paragraphs 0041, 0042, 0048, and 0058 of JP2013-206315A, the contents of which are incorporated in the present specification.

### <Etching Step>

In a case where the substrate is the substrate having a conductive layer, the above-described pattern forming method preferably includes a step (etching step) of etching, using the pattern formed by the step X3 (or the step X4) and the step Y3 (or the step Y2B) as an etching resist film, the conductive layer in a region where the etching resist film is not disposed.

As a method of the etching treatment, a method by wet etching, which is described in paragraphs 0048 to 0054 of JP2010-152155A, a method by dry etching such as a known plasma etching, or the like can be adopted.

For example, examples of the method of the etching treatment include a wet etching method by immersing in an etchant, which is generally performed. As the etchant used for the wet etching, an acidic type or alkaline type etchant may be appropriately selected according to the etching target.

Examples of the acidic type etchant include aqueous solutions of acidic component alone, such as hydrochloric acid, sulfuric acid, hydrofluoric acid, and phosphoric acid, and mixed aqueous solutions of an acidic component and a salt such as ferric chloride, ammonium fluoride, and potassium permanganate. As the acidic component, a component in which a plurality of acidic components is combined may be used.

Examples of the alkaline type etchant include aqueous solutions of alkaline component alone, such as sodium hydroxide, potassium hydroxide, ammonia, organic amine, and a salt of organic amine such as tetramethylammonium hydroxide, and mixed aqueous solutions of an alkaline component and a salt such as potassium permanganate. As the alkaline component, a component in which a plurality of alkaline components is combined may be used.

A temperature of the etchant is preferably 45° C. or lower. In the method for manufacturing a circuit wiring according to the embodiment of the present invention, the pattern formed by the step X3 (or the step X4) and the step Y3 used as the etching resist film preferably exhibits particularly excellent resistance to the acidic and alkaline etchant in a temperature range of 45° C. or lower. With the above-described configuration, the etching resist film is prevented from peeling off during the etching step, and a portion where the etching resist film does not exist is selectively etched.

After the etching step, in order to prevent contamination of the process line, a washing step of washing the etched substrate and a drying step of drying the washed substrate may be performed as necessary.

### OTHER EMBODIMENTS

In the above-described pattern forming method, it is also preferable to use a substrate having a plurality of conductive layers on both surfaces, and sequentially or simultaneously form patterns on the conductive layers formed on both surfaces.

With such a configuration, it is possible to form a first conductive pattern on one surface of the substrate and form a second conductive pattern on the other surface. It is also preferable to form the patterns from both surfaces of the base material by the roll-to-roll.

### [Manufacturing Method of Circuit Wiring]

The transfer film may be used for manufacturing a circuit wiring.

A manufacturing method of the circuit wiring is not particularly limited may be a manufacturing method of a circuit wiring using the above-described transfer film, but it is preferable to include, in the following order, a step (bonding step) of bringing a surface of the photosensitive layer in the transfer film on an opposite side of a temporary support side into contact with a conductive layer in a substrate having a conductive layer to bond the transfer film and the substrate having a conductive layer, a step (first exposing step) of exposing the photosensitive layer in the bonded transfer film in a patterned manner, a step (etching resist film forming step) of developing the exposed photosensitive layer with an alkali developer to form a patterned etching resist film, a step (etching step) of etching the conductive layer in a region on which the etching resist film is not disposed, and a step (peeling step) of peeling off the pattern.

In the method for manufacturing a circuit wiring according to the embodiment of the present invention, all of the bonding step, the first exposing step, and the alkali developing step can be performed by the same procedure as in the step X1, the step X2, and the step X3 of the embodiment 1 of the pattern forming method described above.

In addition, in the method for manufacturing a circuit wiring according to the embodiment of the present invention, it is preferable that a temporary support peeling step is further provided between the bonding step and the first exposing step or between the first exposing step and the etching resist film forming step.

In addition, in a case where the photosensitive layer is a photosensitive layer formed of the photosensitive composition of the embodiment X-1-a3, in the above-described etching resist film forming step, a treatment (second exposing treatment) of further exposing the pattern obtained through the first exposing step and the development treatment may be performed after the development treatment. The second exposure treatment can be performed by the same procedure as in the step Y2Q of the embodiment 2 of the pattern forming method described above.

In addition, the substrate having a conductive layer, which is used in the method for manufacturing a circuit wiring according to the embodiment of the present invention, is the same as the substrate having a conductive layer, which is used in the above-described step X1. In addition, the method for manufacturing a circuit wiring according to the embodiment of the present invention may include a step other than the above-described steps. Examples of other steps include the same steps as the optional step which may be included in the embodiment 1 and embodiment 2 of the pattern forming method.

In the method for manufacturing a circuit wiring according to the present invention, it is also preferable that the steps from the bonding step to the etching step described above are regarded as one set and repeated a plurality of times.

The film used as the etching resist film can also be used as a protective film (permanent film) for the formed circuit wiring.

### [Manufacturing Method of Semiconductor Package]

Examples of a manufacturing method of a semiconductor package include a known manufacturing method such as a manufacturing method of a build-up substrate.

Specific examples thereof include a manufacturing method including the step Z1 to the step Z4 in this order.

Step Z1: step of forming a photosensitive layer on a base material having a conductive layer using a photosensitive composition or a transfer film

Step Z2: step of exposing the photosensitive layer in a patterned manner

Step Z3: step of developing the exposed photosensitive layer with an alkali developer to form a pattern having a via

Step Z4: step of forming a circuit pattern on the pattern

The method of forming the substrate having a conductive layer, the photosensitive composition, the transfer film, and the photosensitive layer in the step Z1 is as described above.

Examples of the step Z2 include the step X2.

### [Step Z3]

The step Z3 is a step of developing the exposed photosensitive layer with an alkali developer to form a pattern having a via.

Examples of a method of development with an alkali developer include the method of development using an alkali developer in the step X3.

Examples of a shape of the via included in the above-described pattern include a quadrangular, a trapezoidal, and an inverted trapezoidal as a cross-sectional shape; and a circular and a quadrangular as a front shape (a shape of the via in a case of observing the via from a direction in which the via bottom is visible).

As the shape of the via included in the above-described pattern, from the viewpoint of improving attachment property of a via wall surface to a plated copper, a reverse trapezoid is preferable as the cross-sectional shape.

A size (diameter) of the above-described via is usually 300 μm or less, preferably 200 m or less, more preferably less than 40 μm, still more preferably 30 μm or less, even more preferably 20 μm or less, particularly preferably 10 μm or less, and most preferably 5 μm or less. The lower limit thereof is preferably 15 μm or more and more preferably 20 μm or more. The number of the above-described vias may be 1 or 2 or more, and is preferably 2 or more.

### [Step Z4]

The step Z4 is a step of forming a circuit pattern on the above-described pattern.

As a method of forming the circuit pattern, a semi-additive process is preferable from the viewpoint that a fine wiring can be formed.

In the semi-additive process, first, a seed layer is formed by performing an electroless copper plating treatment on the entire surface of the via bottom, the via wall surface, and the pattern after the above-described step Z3 using a palladium catalyst or the like.

The above-described seed layer is for forming a power feeding layer for performing the electrolytic copper plating, and a thickness of the seed layer is preferably 0.1 to 2.0 μm. In a case where the thickness of the above-described seed layer is 0.1 μm or more, the tendency is that the deterioration in connection reliability during the electroless copper plating can be suppressed, and in a case where the thickness of the above-described seed layer is 2.0 μm or less, the tendency is that it is not necessary to increase the etching amount in a case of flash-etching the seed layer between the wiring lines, and the damage to the wiring lines during the etching can be suppressed.

The electroless copper plating treatment is performed by precipitating metallic copper on the surface of the pattern having a via by a reaction between copper ions and a reducing agent.

Examples of the electroless plating treatment method and the electrolytic plating treatment method include known plating treatment methods.

As the catalyst in the electroless plating treatment step, a palladium-tin mixed catalyst is preferable. An average primary particle diameter of the above-described mixed catalyst is preferably 10 nm or less. In addition, as the plating composition of the electroless plating treatment step, it is preferable to contain hypophosphorous acid as a reducing agent.

Examples of a commercially available product of the electroless copper plating liquid include “MSK-DK” manufactured by Atotech Japan K.K. and “SULKACUP (registered trademark) PEA ver. 4” series manufactured by Uemura Kogyo Co., Ltd.

It is preferable that, after the electroless copper plating treatment, the surface of the photosensitive layer in the transfer film on the side opposite to the temporary support is thermocompression-bonded to the electroless copper plating by a roll laminator.

From the viewpoint that the thickness of the above-described photosensitive layer can be higher than the wiring line height after the electro copper plating, the thickness of the photosensitive layer is preferably 5 to 30 μm.

After the thermal compression bonding of the transfer film, the photosensitive layer is exposed through, for example, a mask on which a desired wiring pattern is drawn. Examples of the above-described exposing method include the exposing method in the step X2.

After the exposure, the support of the transfer film is peeled off, and the exposed photosensitive layer is developed with an alkali developer to form a pattern. In addition, after the above-described pattern is formed, the development residue of the photosensitive layer may be removed using a plasma or the like.

After the development, the copper circuit layer is formed and the via filling is performed by performing the electro copper plating.

After the electro copper plating, the pattern is peeled off using an alkaline aqueous solution or an amine-based peeling agent.

After the pattern is peeled off, the seed layer between the wiring lines is removed (flash etching).

The flash etching is performed using, for example, sulfuric acid, an acidic solution such as hydrogen peroxide, and an oxidative solution. Specific examples thereof include “SAC” manufactured by JCU Corporation and “CPE-800” manufactured by Mitsubishi Gas Chemical Company, Inc. After the flash etching, removal of palladium or the like adhering to a part between the wiring lines is performed as necessary. The removal of palladium can be performed using an acidic solution such as nitric acid and hydrochloric acid.

It is preferable to perform a post-baking treatment after the peeling of the pattern or after the flash etching step. The post-baking treatment sufficiently thermosets the unreacted thermosetting component, and further improves the electrical insulation reliability, the curing characteristics, and the adhesive strength with the plated copper.

The thermal curing conditions are preferably a curing temperature of 150° C. to 240° C. and a curing time of 15 to 500 minutes.

The method for manufacturing the semiconductor package may include a roughening step of roughening a pattern having a via. It is preferable that the above-described roughening step is performed after the above-described step Z3 and before the above-described step Z4.

By performing the roughening step, the above-described patterned surface can be roughened, and the adhesiveness with the circuit wiring can be improved. In addition, the smearing can be removed at the same time.

Examples of the roughening step include a known desmutting treatment, and a treatment of bringing the roughening liquid into contact is preferable.

Examples of the roughening liquid include a roughening liquid containing chromium and sulfuric acid, a roughening liquid containing an alkali permanganate (for example, a sodium permanganate roughening liquid or the like), and a roughening liquid containing sodium fluoride, chromium, and sulfuric acid.

Each of the above-described steps is repeated according to the required number of layers, thereby manufacturing a semiconductor package. In addition, it is preferable that a solder resist is formed on the outermost layer.

### [Manufacturing Method of Touch Panel]

The transfer film may be used for manufacturing a touch panel.

The manufacturing method of a touch panel may be a manufacturing method of a touch panel using the above-described transfer film, but it is preferable to include, in the following order, a step (bonding step) of bringing a surface of the photosensitive layer in the transfer film on an opposite side of a temporary support side into contact with a conductive layer (preferably, a patterned conductive layer; specifically, a touch panel electrode pattern or a conductive pattern such as a wiring line) in a substrate having a conductive layer to bond the transfer film and the substrate having a conductive layer, a step (first exposing step) of exposing the photosensitive layer in the bonded transfer film in a patterned manner, and a step (protective film or insulating film forming step) of developing the exposed photosensitive layer with alkali developer to form a patterned protective film or insulating film of the conductive layer.

### [Manufacturing Method of Semiconductor Device]

As a manufacturing method of a semiconductor device, a known manufacturing method can be applied.

Specific examples thereof include a manufacturing method of a semiconductor device, including the above-described pattern forming method or the above-described manufacturing method of a semiconductor package.

Examples of the semiconductor device include various semiconductor devices such as a semiconductor package provided in an electrical product (for example, a computer, a mobile phone, a digital camera, and a television) and a vehicle (for example, a motorcycle, an automobile, a train, a ship, and an airplane).

### [Semiconductor Package]

The semiconductor package is not particularly limited as long as it includes a pattern (cured film) obtained using the above-described photosensitive composition or the photosensitive layer of the above-described transfer film.

The cured film may be used as an insulating film, and may be used as an insulating film in a so-called build-up substrate.

### Examples

Hereinafter, the present invention will be described in detail with reference to Examples. The material, the amount used, the proportion, the process contents, the process procedure, and the like shown in the following examples can be appropriately changed, within a range not departing from the gist of the present invention. Therefore, the scope of the present invention should not be construed as being limited to Examples.

In Examples, unless otherwise specified, “part” and “%” mean “part by mass” and “% by mass”, respectively.

### [Preparation of Photosensitive Composition]

Various components were mixed to obtain a mixed solution as shown in the following tables. Furthermore, the above-described mixed solution was diluted so that solid content:MEK (methyl ethyl ketone):PGMEA (propylene glycol monomethyl ether acetate) was 36% by mass:50% by mass:14% by mass. In a case where the silica was not a slurry, the silica was dispersed in a 20% by mass MEK solution and then finally mixed with the other components.

In addition, the obtained mixed solution was diluted 100 times (on a mass basis) using PGMEA to produce a sample for particle size measurement. Using the produced sample for particle size measurement, it was confirmed that the particle size of the filler was within +5% of the particle size shown in Table 1, by a Zetasizer Nano ZS (particle size measurement range: 0.3 nm to 10 μm, peak mode range: 0.6 nm to 8.9 μm, measurement principle: dynamic light scattering method). In a case where the sample was not in the form of target granular shape, the sample was dispersed using an ultrasound homogenizer (Sonifier 450, output: 400 W, frequency: 20 Hz) to produce the sample for particle size measurement.

### [Compound A]

ZFR-1491H: KAYARAD ZFR-1491H, bisphenol F-type carboxylic acid-modified epoxy (meth)acrylate resin (Mw=12,000, acid value: 98 mgKOH/g, viscosity: 50 Pa s, concentration of solid contents: 67.5% by mass, PGMEA solution), manufactured by Nippon Kayaku Co., Ltd.
CCR-1171: KAYARAD CCR-1171, cresol novolac-type carboxylic acid-modified epoxy (meth)acrylate resin (Mw=7,500, acid value: 99 mgKOH/g, viscosity: 39 Pa s, concentration of solid contents: 65% by mass, PGMEA solution), manufactured by Nippon Kayaku Co., Ltd.
ZCR-1569H: KAYARAD ZCR-1569H, biphenyl-type carboxylic acid-modified epoxy (meth)acrylate resin (Mw=4,500, acid value: 99 mgKOH/g, viscosity: 37 Pa s, concentration of solid contents: 69% by mass, PGMEA solution), manufactured by Nippon Kayaku Co., Ltd.
ZCR-1797H: KAYARAD ZCR-1797H, biphenyl-type carboxylic acid-modified epoxy (meth)acrylate resin (Mw=8,000, acid value: 101 mgKOH/g, viscosity: 10 Pa s, concentration of solid contents: 61% by mass, PGMEA solution), manufactured by Nippon Kayaku Co., Ltd.
ZAR-2051H: KAYARAD ZAR-2051H, bisphenol A-type carboxylic acid-modified epoxy (meth)acrylate resin (Mw=9,500, acid value: 71 mgKOH/g, viscosity: 37 Pa s, concentration of solid contents: 67.5% by mass, PGMEA solution), manufactured by Nippon Kayaku Co., Ltd.
UC-3910: ARUFON UC-3000 (styrene/acrylic acid=71% by mass/29% by mass, acid value: 218 mgKOH/g), acrylic resin having a carboxy group, manufactured by TOAGOSEI CO., LTD.
Resin X1: resin shown below, modified phenol resin having an acid group (Mw=7,000, acid value: 342 mgKOH/g)

The resin X1 was synthesized by reacting “H4” (phenol novolac resin, manufactured by LIGNITE CORPORATION., molecular weight: 5,000 to 8,000) with methyl chloroacetate under basic conditions to hydrolyze an ester bond. The obtained resin X was diluted with PGMEA to prepare a 40% by mass PGMEA solution, which was used for preparing the photosensitive composition.

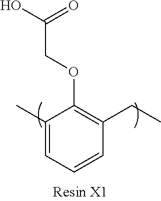

Tris(2-carboxyethyl) isocyanurate: acid value: 487 mgKOH/g, manufactured by Tokyo Chemical Industry Co., Ltd.

### [Compound 3]

9-Methylacridine: manufactured by Tokyo Chemical Industry Co., Ltd.
Acridine: manufactured by Tokyo Chemical Industry Co., Ltd.
9-Phenylacridine: manufactured by Tokyo Chemical Industry Co., Ltd.

### [Filler]

SC-2050 MB: spherical silica slurry, epoxy silane surface-treated product, concentration of solid contents: 70% by mass, MEK slurry, manufactured by Admatechs Co., Ltd.
KE-S30: Sea Foster KE-S30, spherical silica, no surface treatment, concentration of solid contents: 100% by mass, manufactured by Nippon Shokubai Co., Ltd.
NHM-3N: spherical silica, trimethylsilyl surface treatment, concentration of solid contents: 100% by mass, manufactured by Tokuyama Corporation
YA050C-MJE: spherical silica slurry, methacrylic surface-treated product, concentration of solid contents: 50% by mass, MEK slurry, manufactured by Admatechs Co., Ltd.
MEK-EC-2430Z: spherical silica slurry, epoxy silane surface-treated, concentration of solid contents: 30% by mass, manufactured by Nissan Chemical Corporation
ASA: barium sulfate, no surface treatment, concentration of solid contents: 100% by mass, manufactured by Japan Solvay Company
AZ: AZ filler, titanium-doped spherical glass filler, no surface treatment, concentration of solid contents: 100% by mass, manufactured by Asahi Glass Co., Ltd.

### [Epoxy Compound]

jER828EL: bisphenol A-type epoxy compound, manufactured by Mitsubishi Chemical Corporation
EPICLON N-770: phenol novolac-type epoxy compound, manufactured by DIC Corporation
TECHMORE VG3101L: bisphenol A-type trifunctional epoxy compound, manufactured by Printek Inc.

### [Surfactant]

F551A: MEGAFACE (registered trademark) F551A, fluorine-based surfactant, manufactured by DIC Corporation
EXP. S-310-2: silicone-based surfactant, manufactured by DIC Corporation
BYK-333: polyether-modified polymethylsiloxane-type surfactant, manufactured by BYK Chemie

### [Production of Transfer Film]

The obtained photosensitive composition was applied onto a temporary support (PET film, LUMIRROR 16FB40, thickness: 16 μm, manufactured by Toray Industries, Inc.), and dried to form a photosensitive layer. A thickness of the above-described photosensitive layer was adjusted to a film thickness shown in the following tables.

Next, a cover film (polypropylene film, FG-201, thickness: 30 μm, manufactured by Oji F-Tex Co., Ltd.) was provided on the photosensitive layer to obtain each transfer film.

### [Various Evaluations]

### [Molar Absorption Coefficient of Compound β]

The molar absorption coefficient of the compound β at a wavelength of 365 nm was measured by the following procedure.

The compound β (10 mg) was added to acetonitrile (500 mL), and the mixture was stirred at 500 rpm for 20 minutes to obtain a measurement solution. An appropriate amount of the above-described measurement solution was used, and an absorbance was measured using a spectrophotometer UV-2400PC (manufactured by Shimadzu Corporation). The molar absorption coefficient at a wavelength of 365 nm was calculated from the obtained absorbance at a wavelength of 365 nm according to Beer-Lambert Law. In this case, an absorbance of only acetonitrile was measured as a blank, and the molar absorption coefficient of the compound β at a wavelength of 365 nm was calculated by subtracting the absorbance of the measurement solution at a wavelength of 365 nm. In a case where the compound β was insoluble in acetonitrile, the acetonitrile may be appropriately changed to a solvent for dissolving the compound β.

### [Coefficient of Thermal Expansion (CTE) and Glass Transition Temperature (Tg)]

The obtained transfer film was exposed from the opposite side of the photosensitive layer of the temporary support in the transfer film using an ultra-high pressure mercury lamp. In this case, an integrated exposure amount measured with a 365 nm wavelength illuminance meter was 500 mJ/cm². After standing for 30 minutes after the exposure, the cover film was peeled off, and the photosensitive layer was developed with a 1% by mass aqueous solution of sodium carbonate (liquid temperature: 25° C.) as a developer for 60 seconds.

After the development, the photosensitive layer was rinsed with pure water for 20 seconds, and then air was blown to remove the moisture. Thereafter, the entire surface was exposed from the surface side exposed by peeling off the cover film using a high pressure mercury lamp. In this case, an integrated exposure amount measured with a 365 nm wavelength illuminance meter was 1,000 mJ/cm². After the exposure, the temporary support was peeled off from the obtained sample, and the sample was heat-treated at 160° C. for 180 minutes. A sample was cut out after the heat treatment to produce a sample for evaluation.

The sample for evaluation (19 mm×5 mm) was produced, and CTE and Tg were measured using TMA (TA Instruments—TMA 450EM). The measurement conditions were set to a temperature rising rate of 5° C./min, a distance between chucks of 16 mm, and a load of 20 mN. The measurement was performed in a temperature range of 25° C. to 300° C., and the CTE was calculated in a temperature range of 25° C. to “Tg −(minus) 20” ° C. during temperature rise. The measurement was performed on three samples, and an average value thereof was used.

### (Evaluation Standard of CTE)

A: 50 ppm/K or less
B: more than 50 ppm/K and 100 ppm/K or less
C: more than 100 ppm/K

### (Evaluation Standard of Tg)

A: 140° C. or higher
B: 100° C. or higher and lower than 140° C.
C: lower than 100° C.

### [Decarboxylation Reaction]

The photosensitive composition was applied onto a silicon wafer base material such that a thickness after drying was 10.0 μm, and dried at 80° C. for 2 minutes to form a photosensitive layer. Thereafter, the entire surface was exposed from a side of the photosensitive layer opposite to the above-described base material using an ultra-high pressure mercury lamp, and developed with a 1% by mass sodium carbonate aqueous solution at 23° C. for 35 seconds. An integrated exposure amount in the exposure, which was measured with a 365 nm wavelength illuminance meter, was 300 mJ/cm².

At this time, IR spectra of the photosensitive layer before the exposure and the cured film after the development were measured, and a rate of change in a case where both peaks in the vicinity of 1700 cm⁻¹ were compared was evaluated based on the following standard.

### (Evaluation Standard of Decarboxylation Reaction)

A: rate of change in peak after the development with respect to peak before the exposure was 10% or more.
B: rate of change in peak after the development with respect to peak before the exposure was 5% or more and less than 10%.
C: rate of change in peak after the development with respect to peak before the exposure was less than 5%.

### [Photolithography Properties]

Photolithography properties were evaluated using a 1% by mass sodium carbonate aqueous solution.

The photosensitive composition was applied onto a glass (Corning glass, 5 cm in length×5 cm in width×1.1 mm in thickness) and dried so that a thickness after drying was 10 μm, thereby forming a photosensitive layer.

The obtained photosensitive layer was exposed in a patterned manner using an ultra-high pressure mercury lamp. At this time, an exposure mask having a plurality of circular light shielding portions of φ50 μm was used. An interval between the circular light shielding portions of the above-described exposure mask (a distance from a center of a circle to a center of a circle) was 300 μm. In this case, an integrated exposure amount measured with a 365 nm wavelength illuminance meter was 500 mJ/cm².

After standing for 30 minutes after the exposure, development was performed with a 1% by mass aqueous solution of sodium carbonate (liquid temperature: 25° C.) as a developer for 60 seconds. After the development, the photosensitive layer was rinsed with pure water for 20 seconds, and then air was blown to remove the moisture, thereby forming a hole (non-exposed portion). In the obtained sample, a film thickness of the non-exposed portion and a film thickness of the exposed portion were measured at three points each, an average value of differences (corresponding to hole depths) therebetween was obtained, and the sample was evaluated according to the following standard.

### (Evaluation Standard of Photolithography Properties)

A: difference between the film thickness of the non-exposed portion and the film thickness of the exposed portion was 8 μm or more and 10 μm or less.
B: difference between the film thickness of the non-exposed portion and the film thickness of the exposed portion was 5 μm or more and less than 8 μm.
C: difference between the film thickness of the non-exposed portion and the film thickness of the exposed portion was less than 5 μm.

### [Cycle Test]

The photosensitive composition was applied onto a copper pattern (line/space=50 μm/50 μm) having a thickness of 5 μm, which was formed as a wiring line in a comb shape on a silicon wafer base material, such that a film thickness of the photosensitive layer on a copper line was 10 μm, and dried to form a photosensitive layer.

Next, the obtained photosensitive layer was exposed using an ultra-high pressure mercury lamp. In this case, an integrated exposure amount measured with a 365 nm wavelength illuminance meter was 500 mJ/cm². After the exposure, development was performed with a 1% by mass aqueous solution of sodium carbonate (liquid temperature: 25° C.) as a developer for 60 seconds. After the development, the photosensitive layer was rinsed with pure water for 20 seconds, and then air was blown to remove the moisture. After the development, the photosensitive layer was further exposed using a high pressure mercury lamp. In this case, an integrated exposure amount measured with a 365 nm wavelength illuminance meter was 1,000 mJ/cm². After the exposure, the photosensitive layer was heat-treated at 160° C. for 180 minutes to produce a sample for measurement, which had a cured film. The measurement sample was left in a vapor phase at a temperature of −40° C. or 120° C. for 30 minutes using a vapor phase cold/heat tester, this cycle was repeated 100 times, and then the number of cracks in a region of 5 cm×5 cm of the cured layer was observed and evaluated according to the following standard.

### [Evaluation Standard of Cycle Test]

A: number of cracks was 3 or less.
B: number of cracks was more than 3 and 15 or less.
C: number of cracks was more than 15.

Hereinafter, the content of various components and the evaluation results are shown.

The column of “Concentration of solid contents (% by mass)” indicates the concentration of solid contents (% by mass) of the various components in the photosensitive composition with respect to the total solid content.

The column of “Molar absorption coefficient (365 nm)” indicates the molar absorption coefficient (L/(mol·cm)) of the compound β at a wavelength of 365 nm.

The column of “mol % with respect to carboxy group” indicates the total number (mol %) of structures capable of accepting an electron, which are included in the compound B, with respect to the total number of carboxy groups included in the compound A.

“Particle diameter” indicates the average primary particle diameter of the filler.

“-” in the column of “Evaluation” in Comparative Example 2 indicates that the cured film could not be obtained because the exposed portion was not cured by the exposure, and the measurement could not be performed. That is, since the photolithography properties were low and the pattern could not be formed, the evaluation of the CTE and Tg could not be performed.

“Remainder” indicates that the total content (% by mass) of the components other than the surfactant (the compound A, the compound β, the filler, and the epoxy compound) was subtracted from the total solid content (100% by mass) in each of Examples and Comparative Examples.

TABLE 1

| | [symbol] | | | | | | | | | | | | | | | | | | | | | | | | | | |
|---|---|---|---|---|---|---|---|---|---|---|---|---|---|---|---|---|---|---|---|---|---|---|---|---|---|---|---|
| | | | | | [symbol] | | | | | | | | | | [symbol] | | | | | | | | | | | | |
| | [symbol] | | | | | | | | [symbol] | [symbol] | | | | | [symbol] | | | | [symbol] | | | | | | | | |
| | | | | [symbol] | | [symbol] | | [symbol] | [symbol] | | | | [symbol] | | | | | [symbol] | | | [symbol] | [symbol] | | | | | |
| | | [symbol] | [symbol] | [symbol] | | [symbol] | [symbol] | [symbol] | [symbol] | | | [symbol] | [symbol] | | | [symbol] | [symbol] | [symbol] | | [symbol] | [symbol] | [symbol] | [symbol] | | | | |
| | | [symbol] | [symbol] | [symbol] | | [symbol] | [symbol] | [symbol] | [symbol] | | [symbol] | [symbol] | [symbol] | [symbol] | | [symbol] | [symbol] | [symbol] | | [symbol] | [symbol] | [symbol] | | | [symbol] | [symbol] | [symbol] |
| | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | [symbol] | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | [symbol] | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |

[symbol]

indicates data missing or illegible when filed

TABLE 2

| | [symbol] | | | | | | | | | | | | | | | | | | | | | | | | | | |
|---|---|---|---|---|---|---|---|---|---|---|---|---|---|---|---|---|---|---|---|---|---|---|---|---|---|---|---|
| | | | | | [symbol] | | | | | | | | | | | | | | | | | | | | | | |
| | | | | | | | | | [symbol] | | | | | | [symbol] | | | | | | | | | | | | |
| | [symbol] | | | | | | | | [symbol] | [symbol] | | | | | [symbol] | | | | [symbol] | | | | | | | | |
| | | | | [symbol] | | [symbol] | | [symbol] | [symbol] | | | | [symbol] | | | | | [symbol] | | | [symbol] | [symbol] | | | | | |
| | | | [symbol] | [symbol] | | [symbol] | [symbol] | [symbol] | [symbol] | | | [symbol] | [symbol] | | | [symbol] | [symbol] | [symbol] | | [symbol] | [symbol] | [symbol] | [symbol] | | | | |
| | | [symbol] | [symbol] | [symbol] | | [symbol] | [symbol] | [symbol] | [symbol] | | [symbol] | [symbol] | [symbol] | [symbol] | | [symbol] | [symbol] | [symbol] | | [symbol] | [symbol] | [symbol] | | | [symbol] | [symbol] | [symbol] |
| | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| | [symbol] | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| | [symbol] | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | | | | | | | | | | | | | | | | | | | | | | | | | | |

[symbol]

indicates data missing or illegible when filed

From the evaluation results shown in the tables, it was confirmed that the photosensitive composition according to the embodiment of the present invention exhibited desired effects.

It was confirmed that, in a case where the average primary particle diameter of the filler was 10 to 300 nm, the decarboxylation reaction further proceeded, and the photolithography properties were also excellent (Examples 1 to 5, 9, and 10).

It was confirmed that, in a case where the content of the filler was 35% to 70% by mass with respect to the total solid content of the photosensitive composition, the CTE was more excellent (Examples 4 and 6 to 8).

It was confirmed that, in a case where the photosensitive composition further contained an epoxy compound, the CTE, Tg, and the cycle test were more excellent (Examples 4, 11, and 12).

### Example 1A to Example 42A

Each transfer film was produced in the same manner as in Examples 1 to 42, except that the temporary support and the cover film used for producing the transfer film were changed to the following materials.
Temporary support: product name “COSMOSHINE (registered trademark) A4160”, manufactured by TOYOBO Co., Ltd., thickness: 50 μm, PET film
Cover film: product name “ALPHAN (registered trademark) E-210F”, manufactured by Oji F-Tex Co., Ltd., thickness: 50 μm, polypropylene film

### Example 1B to Example 42B

Each transfer film was produced in the same manner as in Examples 1 to 42, except that the temporary support and the cover film used for producing the transfer film were changed to the following materials.
Temporary support: product name “COSMOSHINE (registered trademark) A4360”, manufactured by TOYOBO Co., Ltd., thickness: 38 μm, PET film
Cover film: product name “ALPHAN (registered trademark) FG-201”, manufactured by Oji F-Tex Co., Ltd., thickness: 30 μm, polypropylene film

### Example 1C to Example 42C

Each transfer film was produced in the same manner as in Examples 1 to 42, except that the temporary support and the cover film used for producing the transfer film were changed to the following materials.
Temporary support: product name “LUMIRROR (registered trademark) #38-U48”, manufactured by Toray Industries, Inc., thickness: 38 μm, PET film
Cover film: product name “ALPHAN (registered trademark) E-210F”, manufactured by Oji F-Tex Co., Ltd., thickness: 50 μm, polypropylene film

### Example 1D to Example 42D

Each transfer film was produced in the same manner as in Examples 1 to 42, except that the temporary support and the cover film used for producing the transfer film were changed to the following materials.
Temporary support: product name “LUMIRROR (registered trademark) #75-U34”, manufactured by Toray Industries, Inc., thickness: 75 μm, PET film
Cover film: product name “ALPHAN (registered trademark) FG-201”, manufactured by Oji F-Tex Co., Ltd., thickness: 30 μm, polypropylene film

### Example 1E to Example 42E

Each transfer film was produced in the same manner as in Examples 1 to 42, except that the temporary support and the cover film used for producing the transfer film were changed to the following materials.
Temporary support: product name “LUMIRROR (registered trademark) 16KS40”, manufactured by Toray Industries, Inc., thickness: 16 μm, PET film
Cover film: product name “ALPHAN (registered trademark) E-210F”, manufactured by Oji F-Tex Co., Ltd., thickness: 50 μm, polypropylene film

### Example 101

The transfer film of Example 1 was laminated on both surfaces of a glass epoxy base material (CCL-EL190T, thickness: 1.0 mm, manufactured by MITSUBISHI GAS CHEMICAL COMPANY, INC.) on which a circuit pattern had been formed, thereby forming a photosensitive layer on both surfaces of the glass epoxy base material. At this time, a vacuum laminator was used. The lamination was performed under the following conditions using a vacuum laminator manufactured by MCK Co., Ltd.: a substrate temperature of 40° C., a rubber roller temperature of 100° C., a linear pressure of 3 N/cm, and a transportation speed of 2 m/min.

A pattern (φ60 μm) having a via at a predetermined position was formed on the formed photosensitive layer in the same manner as in [Photolithography properties] described above, and then the residue was removed with an aqueous solution of sodium permanganate as a roughening liquid, and an electroless plating treatment was performed. Next, a pattern was formed at a predetermined position using a known dry film resist, and an electrolytic plating treatment was performed. Next, a seed layer etching treatment was performed. Finally, the resist was peeled off in the pattern using a stripper, and a copper wiring line was formed on the cured film by performing a heat treatment (160° C., 1 hour).

The above-described process from the lamination to the heating treatment was performed three times, and finally, a solder resist was formed as an outermost layer, and a semiconductor element was further sealed and mounted to produce a semiconductor package. The obtained semiconductor package was mounted at a predetermined position of a printed wiring board to obtain a semiconductor package substrate. It was confirmed that the obtained semiconductor package substrate normally operated.

A semiconductor package was produced by the same procedure as in Example 101, except that the transfer film of Example 1 was changed to each of the transfer films of Examples 2 to 42, Examples 1A to 42A, Examples 1B to 42B, Examples 1C to 42C, Examples 1D to 42D, and Examples 1E to 42E, and then a semiconductor package substrate was obtained. It was confirmed that all the obtained semiconductor package substrates normally operated.

### EXPLANATION OF REFERENCES

12: temporary support
14: photosensitive layer
16: cover film
100: transfer film

What is claimed is:

1. A photosensitive composition comprising:
a compound A having a carboxy group;
a compound β having a structure in which an amount of the carboxy group included in the compound A is decreased by exposure; and
a filler.

2. The photosensitive composition according to claim 1,
wherein the compound β is a compound B having a structure capable of accepting an electron from the carboxy group included in the compound A in a photoexcited state.

3. The photosensitive composition according to claim 2,
wherein a total number of structures capable of accepting the electron, included in the compound B, is 3 mol % or more with respect to a total number of carboxy groups included in the compound A.

4. The photosensitive composition according to claim 1,
wherein the compound A includes at least one selected from the group consisting of an acrylic resin having a carboxy group, a carboxylic acid-modified epoxy (meth)acrylate resin, a modified phenol resin having a carboxy group, and a compound having a carboxy group and a bisphenol structure.

5. The photosensitive composition according to claim 1,
wherein an acid value of the compound A is 30 to 500 mgKOH/g.

6. The photosensitive composition according to claim 1,
wherein the compound β includes at least one selected from the group consisting of acridine, 9-methylacridine, and 9-phenylacridine.

7. The photosensitive composition according to claim 1,
wherein a molar absorption coefficient of the compound β at a wavelength of 365 nm is more than 1,000 L/(mol·cm).

8. The photosensitive composition according to claim 1,
wherein the filler includes at least one selected from the group consisting of silicon dioxide, boron nitride, barium sulfate, and silicate.

9. The photosensitive composition according to claim 1,
wherein a content of the filler is 10% to 80% by mass with respect to a total solid content of the photosensitive composition.

10. The photosensitive composition according to claim 1,
wherein an average primary particle diameter of the filler is 5 to 1,000 nm.

11. The photosensitive composition according to claim 1,
wherein an average primary particle diameter of the filler is 10 to 300 nm.

12. The photosensitive composition according to claim 1,
wherein a refractive index of the filler is 1.2 to 1.8.

13. The photosensitive composition according to claim 1,
wherein the filler is subjected to a surface treatment.

14. The photosensitive composition according to claim 1, further comprising:
an epoxy compound.

15. The photosensitive composition according to claim 14,
wherein the epoxy compound includes at least one selected from the group consisting of a bisphenol A-type epoxy resin, a bisphenol F-type epoxy resin, a biphenyl-type epoxy resin, a phenol novolac-type epoxy resin, a cresol novolac-type epoxy resin, and a urethane epoxy-type epoxy resin.

16. The photosensitive composition according to claim 14,
wherein the epoxy compound has two or more epoxy groups in one molecule.

17. The photosensitive composition according to claim 14,
wherein an epoxy value of the epoxy compound is 90 to 290 g/eq.

18. The photosensitive composition according to claim 1,
wherein the photosensitive composition contains no polymerizable compound having a molecular weight of 2,000 or less, having an ethylenically unsaturated group, and not having a carboxy group, or
in a case of containing the polymerizable compound, a content of the polymerizable compound is 5% by mass or less with respect to a total solid content of the photosensitive composition.

19. The photosensitive composition according to claim 1,
wherein the photosensitive composition capable of forming a photosensitive layer which can be patterned by exposure and development with an aqueous solution of 1% by mass sodium carbonate at a liquid temperature of 25° C.

20. The photosensitive composition according to claim 1,
wherein a content of the compound A is 15% by mass or more with respect to a total solid content of the photosensitive composition,
a content of the compound β is 1% by mass or more with respect to the total solid content of the photosensitive composition,
a content of the filler is 10% to 80% by mass with respect to the total solid content of the photosensitive composition,
a mass ratio of the content of the filler to the content of the compound A is 0.5 or more,
a mass ratio of the content of the compound β with respect to the content of the compound A is 0.7 or less, and
a mass ratio of the content of the compound β to the content of the filler is 0.5 or less.

21. The photosensitive composition according to claim 2,
wherein a total number of structures capable of accepting the electron, included in the compound B, is 10 mol % or more with respect to a total number of carboxy groups included in the compound A, and
the photosensitive composition contains no polymerizable compound having a molecular weight of 2,000 or less, having an ethylenically unsaturated group, and not having a carboxy group, or in a case of containing the polymerizable compound, a content of the polymerizable compound is 5% by mass or less with respect to a total solid content of the photosensitive composition.

22. A transfer film comprising:
a temporary support; and
a photosensitive layer formed of the photosensitive composition according to claim 1.

23. A cured film obtained by curing the photosensitive composition according to claim 1.

24. A semiconductor package comprising:
the cured film according to claim 23.

25. A pattern forming method comprising, in the following order:
a step of forming a photosensitive layer on a base material using the photosensitive composition according to claim 1;
a step of exposing the photosensitive layer in a patterned manner; and
a step of developing the exposed photosensitive layer with an alkali developer to form a pattern.

26. A manufacturing method of a semiconductor package comprising, in the following order:
a step of forming a photosensitive layer on a base material having a conductive layer, using the photosensitive composition according to claim 1;
a step of exposing the photosensitive layer in a patterned manner;
a step of developing the exposed photosensitive layer with an alkali developer to form a pattern having a via; and
a step of forming a circuit pattern on the pattern.
